(19) United States
(12) Patent Application Publication
(10) Pub. No.: US 2024/0306407 A1
(43) Pub. Date: Sep. 12, 2024

(54) IMAGING DEVICE

(71) Applicant: Panasonic Intellectual Property Management Co., Ltd., Osaka (JP)

(72) Inventors: SOGO OTA, Osaka (JP); YOSHIHIRO SATO, Osaka (JP)

(21) Appl. No.: 18/661,367

(22) Filed: May 10, 2024

Related U.S. Application Data
(63) Continuation of application No. PCT/JP2022/040189, filed on Oct. 27, 2022.

(30) Foreign Application Priority Data
Nov. 18, 2021 (JP) 2021-187518

(51) Int. Cl. H10K 39/32; H10K 39/38

(52) U.S. Cl. CPC H10K 39/32; H10K 39/38

(57) ABSTRACT

An imaging device includes pixels and pixel electrodes. Each of the pixels includes a semiconductor substrate, a photoelectric conversion layer, and a corresponding pixel electrode out of the pixel electrodes. The photoelectric conversion layer converts light into electric charges. The corresponding pixel electrode collects the electric charges. A pitch of the pixel electrodes is greater than a pitch of the pixels.

### BACKGROUND

### 1. Technical Field

The present disclosure relates to an imaging device.

### 2. Description of the Related Art

Various imaging devices have heretofore been proposed. In an imaging device according to an example, light from a subject passes through microlenses and color filters in this order, and is then received by light receiving portions. The microlenses improve light collection rates onto the light receiving portions. The color filters have predetermined light transmission characteristics. The light receiving portions convert the received light into electric signals.

### SUMMARY

In one general aspect, the techniques disclosed here feature an imaging device including: a plurality of pixels; and a plurality of pixel electrodes, in which each of the plurality of pixels includes a semiconductor substrate, a photoelectric conversion layer that converts light into electric charges, and a corresponding pixel electrode out of the plurality of pixel electrodes. The corresponding pixel electrode collects the electric charges. A pitch of the plurality of pixel electrodes is greater than a pitch of the plurality of pixels.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 illustrates schematic sectional views of an imaging device according to a first embodiment;

FIG. 2 is a schematic sectional view for explaining a structure between a microlens and a semiconductor substrate;

FIG. 3 is an explanatory diagram of pitches;

FIG. 4 illustrates schematic sectional views of an imaging device according to a first reference mode;

FIG. 5 illustrates schematic sectional views of an imaging device according to a second reference mode;

FIG. 6 is a conceptual diagram illustrating a bird's-eye view of a pixel region;

FIG. 7 illustrates schematic sectional views of an imaging device according to a second embodiment;

FIG. 8 illustrates schematic sectional views of an imaging device according to a third embodiment;

FIG. 9 illustrates schematic sectional views of an imaging device according to a third reference mode;

FIG. 10 illustrates schematic sectional views of an imaging device according to a fourth embodiment;

FIG. 11 illustrates schematic sectional views of an imaging device according to a fifth embodiment;

FIG. 12 illustrates schematic sectional views of an imaging device according to a sixth embodiment;

FIG. 13 illustrates schematic sectional views of an imaging device according to a fourth reference mode;

FIG. 14 is a schematic plan view of the imaging device according to the sixth embodiment;

FIG. 15 illustrates schematic explanatory diagrams of an imaging device according to a seventh embodiment;

FIG. 16 is an explanatory diagram of pitches;

FIG. 17 illustrates schematic sectional views of an imaging device according to a fifth reference mode;

FIG. 18 is a schematic plan view for explaining separated electrodes according to the seventh embodiment;

FIG. 19 illustrates schematic diagrams for explaining pads according to the seventh embodiment;

FIG. 20 illustrates schematic explanatory diagrams of an imaging device according to an eighth embodiment; and

FIG. 21 is a configuration diagram of a camera system according to an example.

### DETAILED DESCRIPTIONS

Underlying knowledge forming basis of the present disclosure

Light that is incident on an imaging device in a reference direction is likely to be subjected to photoelectric conversion at high efficiency. On the other hand, light that is incident on the imaging device in an oblique direction is likely to be subjected to photoelectric conversion at low efficiency. The oblique direction is a direction deviated from the reference direction.

In an example, light that is incident on an imaging device in a reference direction passes through a microlens and a color filter in this order and then reaches a position suitable for photoelectric conversion. On the other hand, light that is incident on the imaging device in an oblique direction passes through the microlens and the color filter in this order and then reaches a position deviated from the position suitable for photoelectric conversion.

A pixel region includes a central portion and a peripheral portion. At the central portion, the light is incident on the imaging device in the reference direction. Accordingly, it is more likely that photoelectric conversion efficiency is ensured at the central portion. On the other hand, at the peripheral portion, the light is incident on the imaging device in the oblique direction. Accordingly, it is less likely that photoelectric conversion efficiency is ensured at the peripheral portion. Thus, a level of an electric signal obtained at the peripheral portion is prone to be lower than a level of an electric signal obtained at the central portion. As a consequence, a phenomenon that sensitivity at the peripheral portion is lower than sensitivity at the central portion is likely to occur. This phenomenon is called shading.

Techniques for suppressing shading have been known. For example, Japanese Patent No. 2600250 discloses a technique to displace a microlens to a central portion side relative to a light receiving portion. Japanese Patent No. 3551437 discloses a technique to displace a color filter to a central portion side relative to a light receiving portion.

According to investigations conducted by the inventors of the present disclosure, it is not always easy to displace the microlens to the central portion side or to displace the color filter to the central portion side. To be more precise, it is necessary to reduce a pitch of microlenses or to reduce a pitch of color filters in order to realize this configuration. However, the pitch reduction may involve a technique development for microfabrication.

This technique development is not always easy.

In view of the above, the inventors of the present disclosure have studied a technique suitable to suppress shading. To be more precise, the inventors of the present disclosure have studied a technique suitable to suppress shading while reducing the necessity of the technique development for microfabrication.

Summary according to an aspect of the present disclosure

An imaging device according to a first aspect of the present disclosure includes: a plurality of pixels; and a plurality of pixel electrodes. Each of the plurality of pixels includes a semiconductor substrate, a photoelectric conversion layer that converts light into electric charges, and a corresponding pixel electrode out of the plurality of pixel electrodes. The corresponding pixel electrode collects the electric charges. A pitch of the plurality of pixel electrodes is greater than a pitch of the plurality of pixels.

The first aspect is suitable to suppress shading.

According to a second aspect of the present disclosure, for example, in the imaging device according to the first aspect, the imaging device may further include: (a) a plurality of charge accumulating regions that are located in the semiconductor substrate and that accumulate the electric charges, each of the plurality of pixels may further include a corresponding charge accumulating region out of the plurality of charge accumulating regions, and the pitch of the plurality of pixels may be equivalent to a pitch of the plurality of charge accumulating regions. According to a third aspect of the present disclosure, for example, in the imaging device according to the first aspect, the imaging device may further include: (b) a plurality of charge accumulating regions that are located in the semiconductor substrate and that accumulate the electric charges; a plurality of first electric pathways; and a plurality of first connectors, each of the plurality of pixels may further include a corresponding charge accumulating region out of the plurality of charge accumulating regions, a corresponding first electric pathway out of the plurality of first electric pathways, and a corresponding first connector out of the plurality of first connectors, the corresponding first electric pathway may electrically connect the corresponding pixel electrode and the corresponding charge accumulating region and may include the corresponding first connector, the corresponding first connector may be physically connected to the corresponding pixel electrode, and the pitch of the plurality of pixels may be equivalent to a pitch of the plurality of first connectors. According to a fourth aspect of the present disclosure, for example, in the imaging device according to the first aspect, the imaging device may further include: (c) a plurality of charge accumulating regions that are located in the semiconductor substrate and that accumulate the electric charges; a plurality of first electric pathways; and a plurality of second connectors, each of the plurality of pixels may further include a corresponding charge accumulating region out of the plurality of charge accumulating regions, a corresponding first electric pathway out of the plurality of first electric pathways, and a corresponding second connector out of the plurality of second connectors, the corresponding first electric pathway may electrically connect the corresponding pixel electrode and the corresponding charge accumulating region and may include the corresponding second connector, the corresponding second connector may be physically connected to the corresponding charge accumulating region, and the pitch of the plurality of pixels may be equivalent to a pitch of the plurality of second connectors. According to a fifth aspect of the present disclosure, for example, in the imaging device according to the first aspect, the imaging device may further include: (d) a plurality of charge accumulating regions that are located in the semiconductor substrate and that accumulate the electric charges; a plurality of first electric pathways; and a plurality of through holes, each of the plurality of pixels may further include a corresponding charge accumulating region out of the plurality of charge accumulating regions, an insulating film that covers the semiconductor substrate, a corresponding through hole out of the plurality of through holes, the corresponding through hole passing through the insulating film, and a corresponding first electric pathway out of the plurality of first electric pathways, the corresponding first electric pathway may electrically connect the corresponding pixel electrode and the corresponding charge accumulating region and may pass through the corresponding through hole, and the pitch of the plurality of pixels may be equivalent to a pitch of the plurality of through holes.

The definition of each of the second to fifth aspects is an example of a definition of the pitch of the pixels.

According to a sixth aspect of the present disclosure, for example, in the imaging device according to any one of the first to fifth aspects, the imaging device may further include: a plurality of wires, the plurality of pixels may be arrayed to form a plurality of rows and a plurality of columns, on each of the plurality of columns, the pitch of the plurality of pixel electrodes may be greater than the pitch of the plurality of pixels, each of the plurality of wires may extend along a corresponding row out of the plurality of rows, the plurality of wires may be arranged in a direction of the plurality of columns at mutually equal intervals, and the corresponding pixel electrode may overlap a corresponding wire out of the plurality of wires in a plan view.

The layout of the sixth aspect is an example of a layout of the pixel electrodes and the wires.

According to a seventh aspect of the present disclosure, for example, in the imaging device according to any one of the first to sixth aspects, the imaging device may further include: a plurality of separated electrodes; a plurality of second electric pathways; and a plurality of pads, each of the plurality of separated electrodes, a corresponding second electric pathway out of the plurality of second electric pathways, and a corresponding pad out of the plurality of pads may be electrically connected in this order, each of the plurality of separated electrodes may be located between two pixel electrodes located adjacent to each other out of the plurality of pixel electrodes, each of the plurality of separated electrodes may be electrically separated from the two pixel electrodes, a pitch of the plurality of separated electrodes may be different from a pitch of the plurality of pads, and each of the plurality of separated electrodes may overlap the corresponding pad in a plan view.

According to the seventh aspect, it is easy to avoid the occurrence of a region where the separated electrode cannot be electrically connected to the pad by the second electric pathway.

According to an eighth aspect of the present disclosure, for example, in the imaging device according to the seventh aspect, the imaging device may further include: a first wiring layer; and a second wiring layer, the semiconductor substrate, the second wiring layer, the first wiring layer, and the plurality of pixel electrodes may be located in this order, and the second wiring layer may include the plurality of pads.

According to the eighth aspect, it is possible to suppress a variation in characteristics between a pixel having a small area of overlap between the pixel electrode and the pad in a plan view and a pixel having a large area thereof.

According to a ninth aspect of the present disclosure, for example, in the imaging device according to any one of the first to eighth aspects, each of the plurality of pixels may further include a first wiring layer opposed to the corresponding pixel electrode, a pixel region may be formed by the plurality of pixels, the pixel region may include a central portion and a peripheral portion located outside of the central portion, the plurality of pixels may include a central pixel located at the central portion of the pixel region and a peripheral pixel located at the peripheral portion of the pixel region, and when an area of overlap between the corresponding pixel electrode and the first wiring layer in a plan view is defined as an overlapping area, the overlapping area of the central pixel may be equal to the overlapping area of the peripheral pixel.

According to the ninth aspect, it is possible to suppress a variation in characteristics between the central pixel and the peripheral pixel.

According to a tenth aspect of the present disclosure, for example, in the imaging device according to any one of the first to ninth aspects, the imaging device may further include: a plurality of color filters, each of the plurality of pixels may further include a corresponding color filter out of the plurality of color filters, in each of the plurality of pixels, the corresponding color filter, the photoelectric conversion layer, and the corresponding pixel electrode may be arranged in this order, and a pitch of the plurality of color filters may be less than the pitch of the plurality of pixels.

The tenth aspect is suitable to suppress shading.

According to an eleventh aspect of the present disclosure, for example, in the imaging device according to any one of the first to tenth aspects, the imaging device may further include: a plurality of microlenses, each of the plurality of pixels may further include a corresponding microlens out of the plurality of microlenses, in each of the plurality of pixels, the corresponding microlens, the photoelectric conversion layer, and the corresponding pixel electrode may be arranged in this order, and a pitch of the plurality of microlenses may be less than the pitch of the plurality of pixels.

The eleventh aspect is suitable to suppress shading.

According to a twelfth aspect of the present disclosure, for example, in the imaging device according to any one of the first to eleventh aspects, the plurality of pixels may be arrayed to form a plurality of rows and a plurality of columns, on at least one of the plurality of rows, the pitch of the plurality of pixel electrodes may be greater than the pitch of the plurality of pixels, and on at least one of the plurality of columns, the pitch of the plurality of pixel electrodes may be greater than the pitch of the plurality of pixels.

The twelfth aspect is suitable to suppress shading.

According to a thirteenth aspect of the present disclosure, for example, in the imaging device according to the twelfth aspect, on each of the plurality of rows, the pitch of the plurality of pixel electrodes may be greater than the pitch of the plurality of pixels, and on each of the plurality of columns, the pitch of the plurality of pixel electrodes may be greater than the pitch of the plurality of pixels.

The thirteenth aspect is suitable to suppress shading.

Embodiment of the present disclosure will be described below in detail with reference to the drawings. Each of the embodiments described below represents a comprehensive or specific example. Numerical values, shapes, materials, constituents, layout positions and modes of connection of the constituents, steps, the order of the steps, and the like depicted in the following embodiments are examples and are not intended to restrict the present disclosure. Various aspects described in the present specification can be combined with one another as long as there is no contradiction. Meanwhile, of the constituents in the following embodiments, a constituent not defined in an independent claim that represents the highest conception will be described as an optional constituent. In the following description, the constituents having substantially the same function may be denoted by common reference signs and explanations thereof may be omitted as appropriate.

In the embodiments, the terms “above”, “below”, “upper surface”, “lower surface” and so forth are used solely for indicating relative layouts among members and are not used for intention to restrict a posture of an imaging device in use.

In the embodiments, the term “plan view” means a view in a thickness direction of a semiconductor substrate.

An expression “an element A overlaps an element B in a plan view” may be used in the embodiments. This expression means a situation where at least part of the element A overlaps at least part of the element B in a plan view. However, this expression may be interpreted as a situation where “at least part of the element A overlaps the entire element B in a plan view” as long as there is no contradiction in particular. Meanwhile, this expression may be interpreted as a situation where “the entire element A overlaps at least part of the element B in a plan view” as long as there is no contradiction in particular. Otherwise, this expression may be interpreted as a situation where “the entire element A overlaps the entire element B in a plan view” as long as there is no contradiction in particular.

Terms “row”, “column”, “row direction”, and “column direction” may be used in the embodiments. The row direction is a direction in which a row extends. The column direction is a direction in which a column extends. The row direction and the column direction are directions that are different from each other. In a typical example, the row direction and the column directions are directions that are orthogonal to each other. The terms “row”, “column”, “row direction”, and “column direction” are not intended to restrictively interpret a configuration of the imaging device. The terms “row” and the “column” are interchangeable.

A term “via” may be used in the embodiments. In the embodiments, a via hole and a conductor inside thereof are collectively referred to as the “via”.

### First Embodiment

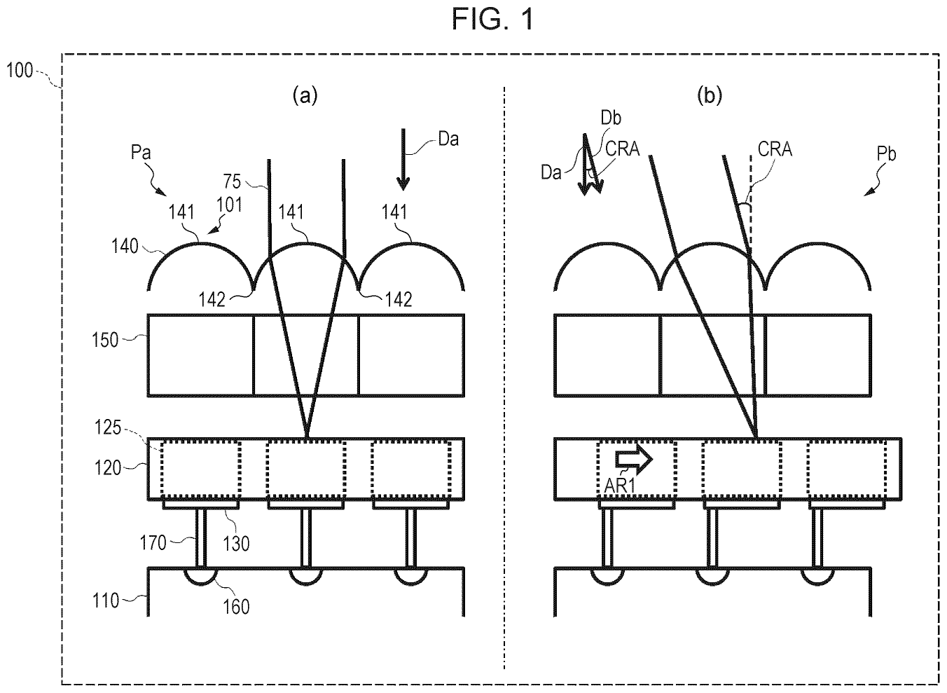

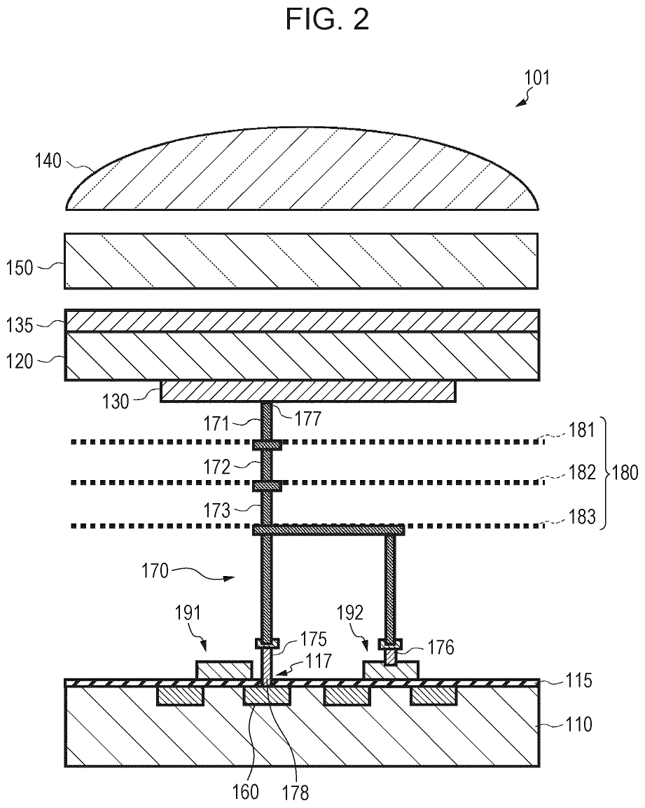

FIG. 1 illustrates schematic sectional views of an imaging device 100 according to a first embodiment. FIG. 2 is a schematic sectional view for explaining a structure between a microlens 140 and a semiconductor substrate 110.

The imaging device 100 includes pixels 101. The pixels 101 constitute a pixel region Px. The pixel region Px includes a central portion Pa and a peripheral portion Pb. The peripheral portion Pb is located outside of the central portion Pa. Note that the terms “central portion Pa” and “peripheral portion Pb” are expressions intended to represent a relative positional relationship between these portions. The term “central” in the “central portion Pa” is not a term intended to restrictively interpret the “central portion Pa”. The term “peripheral” in the “peripheral portion Pb” is not a term intended to restrictively interpret the “peripheral portion Pb”.

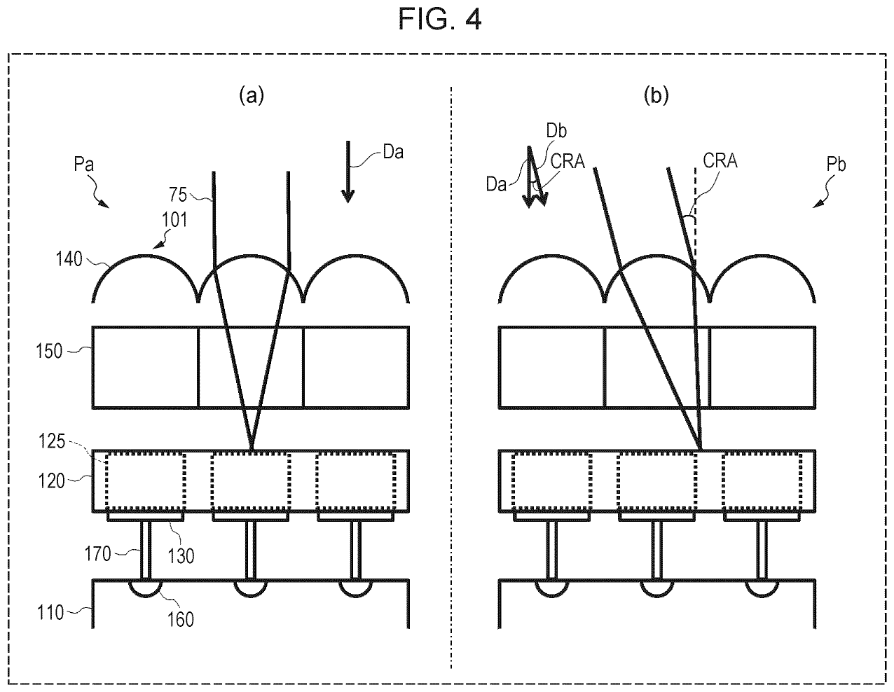

Portion (a) of FIG. 1 illustrates the central portion Pa of the pixel region Px. Portion (b) of FIG. 1 illustrates the peripheral portion Pb of the pixel region Px. Illustration of certain elements such as a counter electrode is omitted in FIG. 1. These features also apply to FIG. 4 and the like to be described below.

In the present embodiment, the pixels 101 are two-dimensionally arrayed. To be more precise, the pixels 101 are arrayed so as to form rows and columns. Nevertheless, the pixels 101 may be one-dimensionally arrayed instead. In other words, the imaging device 100 may be a line sensor.

Each of the pixels 101 includes the semiconductor substrate 110, a charge accumulating region 160, a first electric pathway 170, a photoelectric conversion layer 120, a pixel electrode 130, a counter electrode 135, the microlens 140, and a color filter 150.

The microlens 140, the color filter 150, the counter electrode 135, the photoelectric conversion layer 120, the pixel electrode 130, and the semiconductor substrate 110 are arranged in this order. The charge accumulating region 160 is located in the semiconductor substrate 110. The first electric pathway 170 electrically connects the pixel electrode 130 and the charge accumulating region 160.

Light 75 passes through the microlens 140, the color filter 150, and the counter electrode 135 in this order, and is incident on the photoelectric conversion layer 120. The light 75 is converted into electric charges in the photoelectric conversion layer 120. The electric charges are collected by the pixel electrode 130, sent to the charge accumulating region 160 through the first electric pathway 170, and accumulated in the charge accumulating region 160. A not-illustrated signal detection circuit generates an electric signal out of the electric charges accumulated in the charge accumulating region 160. An image is formed by using the electric signal.

To be more precise, the light 75 is incident on the imaging device 100 in a reference direction Da at the central portion Pa as illustrated in Portion (a) of FIG. 1. The light 75 is incident on the imaging device 100 in an oblique direction Db at the peripheral portion Pb as illustrated in Portion (b) of FIG. 1. The oblique direction Db is a direction deviated from the reference direction Da. The reference direction Da is also referred to as a perpendicular direction. An angle CRA formed between the reference direction Da and the oblique direction Db is referred to as a chief ray angle. The angle CRA has a size corresponding to specifications of the imaging device 100.

Constituents of the imaging device 100 will be specifically described below.

Each microlens 140 improves a light collection rate on the photoelectric conversion layer 120. Examples of a material of the microlens 140 include acrylic resin, a resin containing cyclohexane, and the like. A refractive index of the microlens 140 is in a range from about 1.2 to 1.7, for example.

The color filters 150 have predetermined light transmission characteristics. The color filters 150 contribute to formation of a color image.

In the present embodiment, a color filter 150 of a certain pixel 101 transmits light in a wavelength region corresponding to green. A color filter 150 of another pixel 101 transmits light in a wavelength region corresponding to blue. A color filter 150 of still another pixel 101 transmits light in a wavelength region corresponding to red. In this way, the color filters 150 of the pixels 101 constitute a Bayer layout.

In another example, a color filter 150 of a certain pixel 101 transmits light in a wavelength region corresponding to cyan. A color filter 150 of another pixel 101 transmits light in a wavelength region corresponding to magenta. A color filter 150 of still another pixel 101 transmits light in a wavelength region corresponding to yellow. In this way, the color filters 150 of the pixels 101 constitute a complementary layout.

The photoelectric conversion layer 120 implements photoelectric conversion. Thus, the light 75 is converted into the electric charges. In the illustrated example, a train of a photoelectric conversion film is provided across the pixels 101. The photoelectric conversion layer 120 of each pixel 101 is a portion of the photoelectric conversion film.

In the present embodiment, the photoelectric conversion layer 120 contains an organic material. Nevertheless, the photoelectric conversion layer 120 may contain an inorganic material. Examples of the inorganic material include amorphous silicon, quantum dots, and the like.

Each pixel electrode 130 collects the electric charges generated by the photoelectric conversion layer 120. The pixel electrodes 130 of the pixels 101 located adjacent to each other are electrically separated from each other. Moreover, the pixel electrodes 130 of the pixels 101 located adjacent to each other are located away from each other.

Each pixel electrode 130 defines a photoelectric conversion region 125. The photoelectric conversion region 125 is a region of the photoelectric conversion layer 120 which overlaps the pixel electrode 130 in a plan view. The light 75 that is incident on the photoelectric conversion region 125 is likely to be subjected to photoelectric conversion at high efficiency. On the other hand, the light 75 that is incident on a region of the photoelectric conversion layer 120 which is deviated from the photoelectric conversion region 125 is likely to be subjected to photoelectric conversion at low efficiency.

In the present embodiment, the pixel electrode 130 contains at least one of a metal or a metal compound. Examples of the metal to be contained in the pixel electrode 130 include titanium, tantalum, and the like. Examples of the metal compound to be contained in the pixel electrode 130 include a metal nitride. To be more precise, examples of the metal compound to be contained in the pixel electrode 130 include titanium nitride, tantalum nitride, and the like. Each of the titanium, tantalum, titanium nitride, and tantalum nitride is opaque. However, the pixel electrode 130 may contain a transparent material such as indium tin oxide (ITO).

As illustrated in FIG. 2, the pixel electrode 130 is provided on one surface side of the photoelectric conversion layer 120. The counter electrode 135 is provided on the other surface side of the photoelectric conversion layer 120. In other words, the photoelectric conversion layer 120 is disposed between the pixel electrode 130 and the counter electrode 135. Meanwhile, the counter electrode 135 is provided between the photoelectric conversion layer 120 and the color filter 150.

The counter electrode 135 is configured to transmit the light 75. In the present embodiment, the counter electrode 135 contains a transparent material such as ITO. Sensitivity of the photoelectric conversion layer 120 to the light 75 is adjusted by controlling a voltage at the counter electrode 135.

The first electric pathway 170 is configured to feed an electric current. The first electric pathway 170 may include a via, a plug, and the like. Examples of a material of the first electric pathway 170 include a metal, a metal compound, a semiconductor, and the like.

Each charge accumulating region 160 is a diffused region. The electric charges accumulated in the charge accumulating region 160 are converted into an electric signal by the signal detection circuit. The signal detection circuit is formed by a combination of two or more transistors, for example.

As illustrated in FIG. 2, the imaging device 100 includes wiring layers 180. Each of the pixels 101 includes an insulating film 115, a reset transistor 191, and an amplification transistor 192.

The wiring layers 180 include a first wiring layer 181, a second wiring layer 182, and a third wiring layer 183. The pixel electrode 130, the first wiring layer 181, the second wiring layer 182, the third wiring layer 183, and the semiconductor substrate 110 are disposed in this order. Note that the number of the wiring layers provided to the imaging device 100 may be one layer.

The first electric pathway 170 electrically connects the pixel electrode 130 and the charge accumulating region 160. The first electric pathway 170 includes a first via 171, a second via 172, a third via 173, a first plug 175, and a second plug 176.

The first via 171 electrically and physically connects the pixel electrode 130 and the first wiring layer 181. The second via 172 electrically and physically connects the first wiring layer 181 and the second wiring layer 182. The third via 173 electrically and physically connects the second wiring layer 182 and the third wiring layer 183.

As understood from the foregoing explanation, the first electric pathway 170 includes a first connector 177. The first connector 177 is electrically connected to the pixel electrode 130. Moreover, the first connector 177 is physically connected to the pixel electrode 130. To be more precise, the first connector 177 is included in the first via 171.

The reset transistor 191 and the amplification transistor 192 are included in the signal detection circuit. In the present embodiment, each of the reset transistor 191 and the amplification transistor 192 is a metal oxide semiconductor field effect transistor (MOSFET).

The reset transistor 191 resets the electric charges accumulated in the charge accumulating region 160. In the example of FIG. 2, a source or a drain of the reset transistor 191 constitutes the charge accumulating region 160. The amplification transistor 192 generates the electric signal corresponding to an amount of the electric charges accumulated in the charge accumulating region 160.

The insulating film 115 covers the semiconductor substrate 110. A portion of the insulating film 115 constitutes a gate insulating film of the reset transistor 191. Another portion of the insulating film 115 constitutes a gate insulating film of the amplification transistor 192.

The insulating film 115 is provided with a through hole 117. The first plug 175 passes through the through hole 117. Thus, the first plug 175 is electrically and physically connected to the charge accumulating region 160.

As understood from the foregoing explanation, the first electric pathway 170 includes a second connector 178. The second connector 178 is electrically connected to the charge accumulating region 160. Moreover, the second connector 178 is physically connected to the charge accumulating region 160. To be more precise, the second connector 178 is included in the first plug 175.

As understood from the foregoing explanation, the first electric pathway 170 passes through the through hole 117. To be more precise, it is the first plug 175 that passes through the through hole 117.

The first electric pathway 170 is connected to a gate of the amplification transistor 192. To be more precise, the second plug 176 is connected to the gate of the amplification transistor 192.

Examples of a material of the first via 171 include a metal, a metal compound, and the like. For example, the metal is any of copper, tungsten, cobalt, and the like. The metal compound is any of a metal nitride, a metal oxide, and the like. The first via 171 may be formed from polycrystalline silicon provided with conductivity. These features also apply to the second via 172, the third via 173, the first plug 175, and the second plug 176.

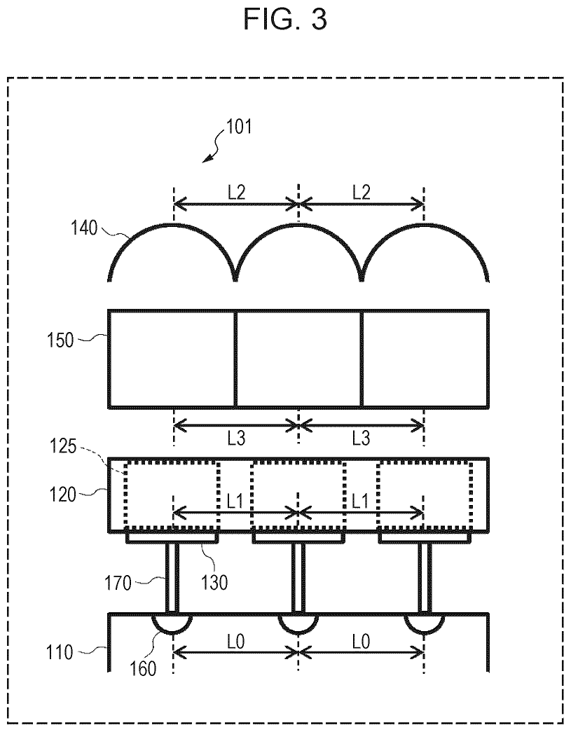

FIG. 3 is an explanatory diagram of pitches. FIG. 3 illustrates a pitch L0 of the pixels 101, a pitch L1 of the pixel electrodes 130, a pitch L2 of the microlenses 140, and a pitch L3 of the color filters 150. For example, the pitch L1 of the pixel electrodes 130 corresponds to a distance between a point of a certain pixel electrode 130 and a corresponding point of an adjacent pixel electrode 130. The point of the pixel electrode 130 is the center of the pixel electrode 130, for example.

Effects of the first embodiment will be described below with reference to FIG. 4. FIG. 4 illustrates schematic sectional views of an imaging device according to a first reference mode.

In the first reference mode, the pitch L1 of the pixel electrodes 130, the pitch L2 of the microlenses 140, and the pitch L3 of the color filters 150 are equal to the pitch L0 of the pixels 101.

As illustrated in Portion (a) of FIG. 4, at the central portion Pa, the light 75 is incident on the imaging device in the reference direction Da. At the central portion Pa, the microlens 140, the color filter 150, and the photoelectric conversion region 125 are disposed substantially on the same axis in the reference direction Da. For this reason, at the central portion Pa, the light 75 passing through the microlens 140 and the color filter 150 in this order is incident on the photoelectric conversion region 125 and is converted into the electric charges at high efficiency.

As illustrated in Portion (b) of FIG. 4, at the peripheral portion Pb, the light 75 is incident on the imaging device in the oblique direction Db. However, at the peripheral portion Pb as well, the microlens 140, the color filter 150, and the photoelectric conversion region 125 are disposed substantially on the same axis in the reference direction Da as with those at the central portion Pa. For this reason, at the peripheral portion Pb, the light 75 passing through the microlens 140 and the color filter 150 in this order is incident on the region of the photoelectric conversion layer 120 deviated from the photoelectric conversion region 125 and is converted into the electric charges at low efficiency.

Due to the aforementioned reasons, in the first reference mode, an amount of the electric charges obtained by photoelectric conversion at the peripheral portion Pb is smaller than an amount of the electric charges obtained by photoelectric conversion at the central portion Pa. Accordingly, a level of the electric signal obtained at the peripheral portion Pb is lower than a level of the electric signal obtained at the central portion Pa. As a consequence, sensitivity at the peripheral portion Pb is lower than sensitivity at the central portion Pa. Hence, shading is generated.

On the other hand, in the first embodiment illustrated in FIG. 1, the pitch L1 of the pixel electrodes 130 is larger than the pitch L0 of the pixels 101. This configuration is suitable to suppress shading.

To be more precise, the light 75 is incident on the imaging device 100 in the reference direction Da at the central portion Pa as illustrated in Portion (a) of FIG. 1. At the central portion Pa, the microlens 140, the color filter 150, and the photoelectric conversion region 125 are disposed substantially on the same axis in the reference direction Da. For this reason, at the central portion Pa, the light 75 passing through the microlens 140 and the color filter 150 in this order is incident on the photoelectric conversion region 125 and is converted into the electric charges at high efficiency.

The light 75 is incident on the imaging device 100 in the oblique direction Db at the peripheral portion Pb as illustrated in Portion (b) of FIG. 1. However, L1>L0 holds up in the first embodiment as mentioned above. Accordingly, at the peripheral portion Pb, the pixel electrode 130 is shifted in an outward direction as compared to that at the central portion Pa. Here, the outward direction is a direction from the central portion Pa toward the peripheral portion Pb. FIG. 1 schematically illustrates this shift by using a first block arrow AR1. Accordingly, in the first embodiment, the microlens 140, the color filter 150, and the photoelectric conversion region 125 are disposed in a direction closer to the oblique direction Db at the peripheral portion Pb as compared to the first reference mode. Hence, the light 75 passing through the microlens 140 and the color filter 150 in this order is incident on the photoelectric conversion region 125 and is converted into the electric charges at high efficiency at the peripheral portion Pb as well.

Due to the aforementioned reasons, in the first embodiment, the phenomenon that the amount of the electric charges obtained by photoelectric conversion at the peripheral portion Pb is smaller than the amount of the electric charges obtained by photoelectric conversion at the central portion Pa can be relaxed as compared to the first reference mode. Accordingly, the phenomenon that the level of the electric signal obtained at the peripheral portion Pb is lower than the level of the electric signal obtained at the central portion Pa can be relaxed. As a consequence, the phenomenon that the sensitivity at the peripheral portion Pb is lower than the sensitivity at the central portion Pa can be relaxed. Thus, shading can be suppressed.

In the meantime, the imaging device may only include photodiodes located in the semiconductor substrate which serve as photoelectric conversion regions. It is not easy to displace a pitch of the photodiodes from the pitch of the pixels.

On the other hand, in the present embodiment, the photoelectric conversion region 125 is the region of the photoelectric conversion layer 120 which overlaps the pixel electrode 130 in a plan view. Displacement of the pitch L1 of the pixel electrodes 130 from the pitch L0 of the pixels 101 is easier than displacement of the pitch of the photodiodes from the pitch of the pixels.

Note that the imaging device 100 of the present embodiment may also include photodiodes located inside the semiconductor substrate 110. Specifically, the imaging device 100 provided with multiple types of photoelectric conversion regions can be realized by using the photodiodes together with the combination of the photoelectric conversion layer 120 and the pixel electrodes 130.

Now, the expression “the pitch L1 of the pixel electrodes 130 is larger than the pitch L0 of the pixels 101” will be described. There may be a case where the number of rows composed of the pixels 101 is equal to one. In this case, this expression means that the following configuration (i) is realized:
(i) The pitch L1 of the pixel electrodes 130 is larger than the pitch L0 of the pixels 101 in this row.

In the configuration (i), the pixels 101 are typically disposed at a regular pitch. The pixel electrodes 130 are typically disposed at a regular pitch. These features also apply to configurations (ii) to (viii) to be described below.

The expression “the pitch L1 of the pixel electrodes 130 is larger than the pitch L0 of the pixels 101” will be described further. There may be a case where the number of columns composed of the pixels 101 is equal to one. In this case, this expression means that the following configuration (ii) is realized:
(ii) The pitch L1 of the pixel electrodes 130 is larger than the pitch L0 of the pixels 101 in this column.

The expression “the pitch L1 of the pixel electrodes 130 is larger than the pitch L0 of the pixels 101” will be described further. There may be a case where the pixels 101 are arrayed to form two or more rows. In this case, this expression means that the following configuration (iii) is realized:
(iii) The pitch L1 of the pixel electrodes 130 is larger than the pitch L0 of the pixels 101 on at least one of the rows.

A case where “the at least one of the rows” in the configuration (iii) includes a certain row and a different row will be taken into consideration. In this case, the pitch L0 on the certain row and the pitch L0 on the different row may be equal to or different from each other. The pitch L1 on the certain row and the pitch L1 on the different row may be equal to or different from each other. These features also apply to the configurations (v), (vii), and (viii) to be described below.

The expression “the pitch L1 of the pixel electrodes 130 is larger than the pitch L0 of the pixels 101” will be described further. There may be a case where the pixels 101 are arrayed to form two or more columns. In this case, this expression means that the following configuration (iv) is realized:
(iv) The pitch L1 of the pixel electrodes 130 is larger than the pitch L0 of the pixels 101 on at least one of the columns.

A case where “the at least one of the columns” in the configuration (iv) includes a certain column and a different column will be taken into consideration. In this case, the pitch L0 on the certain column and the pitch L0 on the different column may be equal to or different from each other. The pitch L1 on the certain column and the pitch L1 on the different column may be equal to or different from each other. These features also apply to the configurations (vi), (vii), and (viii) to be described below.

The expression “the pitch L1 of the pixel electrodes 130 is larger than the pitch L0 of the pixels 101” will be described further. There may be a case where the pixels 101 are arrayed to form two or more rows and two or more columns. In this case, this expression means that at least one selected from the group consisting of the configurations (v) and (vi) below is realized:
(v) The pitch L1 of the pixel electrodes 130 is larger than the pitch L0 of the pixels 101 on at least one of the rows; and
(vi) The pitch L1 of the pixel electrodes 130 is larger than the pitch L0 of the pixels 101 on at least one of the columns.

In the configurations (v) and (vi), the pitch L0 on a certain row and the pitch L0 on a certain column may be equal to or different from each other. The pitch L1 on the certain row and the pitch L1 on the certain column may be equal to or different from each other. These features also apply to the configurations (vii) and (viii) to be described below.

The expression “the pitch L1 of the pixel electrodes 130 is larger than the pitch L0 of the pixels 101” will be described further. In a specific example, the pixels 101 are arrayed to form two or more rows and two or more columns. Moreover, both of the configurations (vii) and (viii) below are realized:
(vii) The pitch L1 of the pixel electrodes 130 is larger than the pitch L0 of the pixels 101 on each of the rows; and
(viii) The pitch L1 of the pixel electrodes 130 is larger than the pitch L0 of the pixels 101 on each of the columns.

The expression “the pitch L1 of the pixel electrodes 130 is larger than the pitch L0 of the pixels 101” has been described above. The pixels 101 are likely to be provided in such a way as to satisfy any of these descriptions. However, it is not always essential to provide all of the pixels included in the imaging device 100 in such a way as to satisfy any of these descriptions. The imaging device 100 may include the pixels 101 provided in such a way as to satisfy this expression and at least one pixel provided in such a way as not to satisfy this expression.

The expression “the pitch L1 of the pixel electrodes 130 is larger than the pitch L0 of the pixels 101” has been described above. These descriptions also apply to descriptions of magnitude relationships of other pitches.

According to a first definition, “the pitch L0 of the pixels 101” is equivalent to a pitch of the charge accumulating regions 160. To be more precise, the pitch L0 is equivalent to the pitch of the charge accumulating regions 160 in a plan view.

According to a second definition, “the pitch L0 of the pixels 101” is equivalent to a pitch of the first connectors 177 of the first electric pathways 170. To be more precise, the pitch L0 is equivalent to the pitch of the first connectors 177 in a plan view.

According to a third definition, “the pitch L0 of the pixels 101” is equivalent to a pitch of the second connectors 178 of the first electric pathways 170. To be more precise, the pitch L0 is equivalent to the pitch of the second connectors 178 in a plan view.

According to a fourth definition, “the pitch L0 of the pixels 101” is equivalent to a pitch of the through holes 117 provided in the insulating film 115. To be more precise, the pitch L0 is equivalent to the pitch of the through holes 117 in a plan view.

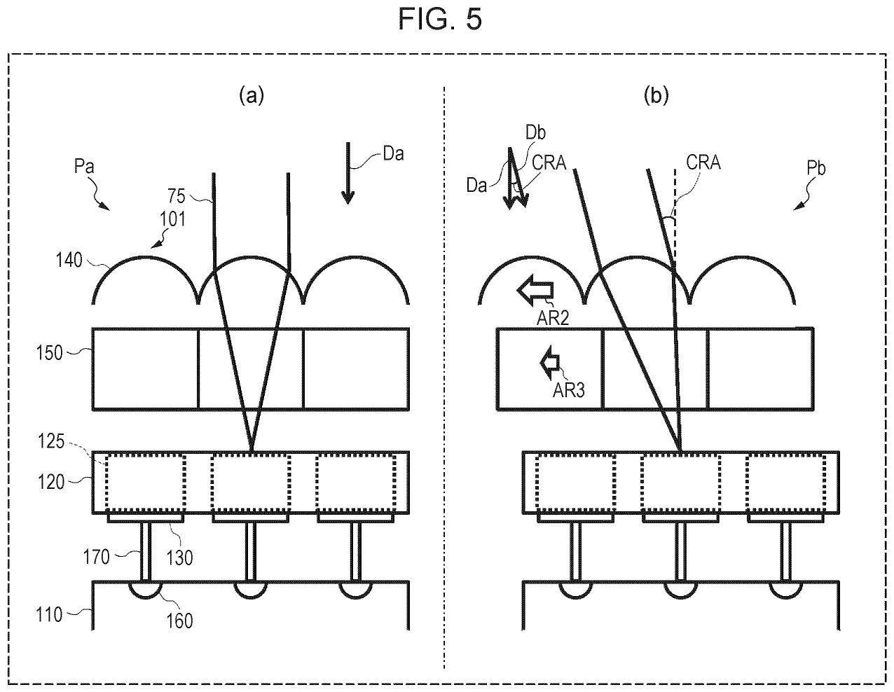

Effects of the first embodiment will be further described below with reference to FIG. 5. FIG. 5 illustrates schematic sectional views of an imaging device according to a second reference mode.

As illustrated in FIG. 5, in the second reference mode, the pitch L1 of the pixel electrodes 130 is equal to the pitch L0 of the pixels 101. The pitch L3 of the color filters 150 is smaller than the pitch L1 of the pixel electrodes 130. The pitch L2 of the microlenses 140 is smaller than the pitch L3 of the color filters 150.

As illustrated in Portion (a) of FIG. 5, at the central portion Pa, the light 75 is incident on the imaging device in the reference direction Da. At the central portion Pa, the microlens 140, the color filter 150, and the photoelectric conversion region 125 are disposed substantially on the same axis in the reference direction Da. For this reason, at the central portion Pa, the light 75 passing through the microlens 140 and the color filter 150 in this order is incident on the photoelectric conversion region 125 and is converted into the electric charges at high efficiency.

As illustrated in Portion (b) of FIG. 5, at the peripheral portion Pb, the light 75 is incident on the imaging device in the oblique direction Db. As mentioned above, L2<L3<L1 holds up in the second reference mode. Accordingly, at the peripheral portion Pb, the microlens 140 and the color filter 150 are shifted in an inward direction as compared to those at the central portion Pa. Here, the inward direction is a direction from the peripheral portion Pb toward the central portion Pa. FIG. 5 schematically illustrates the shift of the microlens 140 by using a second block arrow AR2, and schematically illustrates the shift of the color filter 150 by using a third block arrow AR3. To be more precise, an amount of the shift of microlens 140 is larger than an amount of the shift of color filter 150. Accordingly, in the second reference mode, the microlens 140, the color filter 150, and the photoelectric conversion region 125 are disposed in a direction closer to the oblique direction Db at the peripheral portion Pb as compared to the first reference mode. Hence, the light 75 passing through the microlens 140 and the color filter 150 in this order is incident on the photoelectric conversion region 125 and is converted into the electric charges at high efficiency at the peripheral portion Pb as well.

Due to the aforementioned reasons, in the second reference mode, the phenomenon that the amount of the electric charges obtained by photoelectric conversion at the peripheral portion Pb is smaller than the amount of the electric charges obtained by photoelectric conversion at the central portion Pa can be relaxed more than the first reference mode. Accordingly, the phenomenon that the level of the electric signal obtained at the peripheral portion Pb is lower than the level of the electric signal obtained at the central portion Pa can be relaxed. As a consequence, the phenomenon that the sensitivity at the peripheral portion Pb is lower than the sensitivity at the central portion Pa can be relaxed. Hence, shading can be suppressed.

However, in the second reference mode, the pitch L2 of the microlenses 140 and the pitch L3 of the color filters 150 are smaller than the pitch L0 of the pixels 101. In order to realize this magnitude relationship, it is necessary to reduce the pitch L2 and the pitch L3. This reduction may involve a technique development for microfabrication. This technique development is not always easy.

On the other hand, in the first embodiment illustrated in FIG. 1, the pitch L1 of the pixel electrodes 130 is larger than the pitch L0 of the pixels 101. In realizing the large pitch L1, there is little necessity to conduct the technique development for microfabrication. Due to this reason, the magnitude relationship defined as L1>L0 is suitable to suppress shading while reducing the necessity of the technique development for microfabrication.

In a numerical value example of the second reference mode, the pixels 101 form a matrix of 40 rows by 40 columns. Each of the pitch L0 of the pixels 101 in the row direction and the pitch L0 of the pixels 101 in the column direction is equal to 1 μm. Each of a size of each pixel 101 in the row direction and a size of the pixel 101 in the column direction is equal to 1 μm. Here, an operation to shift the microlens 140 that belongs to the fortieth column on a certain row by 0.5 μm in the inward direction relative to the microlens 140 that belongs to the twenty-first column on the same row will be taken into consideration. In this case, the pitch L2 of the microlenses 140 that belong to the same row is determined as follows. Specifically, a value is obtained by dividing the amount of the shift by the number of the pixels 101 from the twenty-first column to the fortieth column on the aforementioned row. Next, the obtained value is subtracted from the pitch L0. Specifically, L2=1-0.5/20=0.975 μm is calculated. The length 0.975 μm is smaller than the length 1 μm. Accordingly, even when a technique for forming the pixel 101 in the sizes of 1 μm×1 μm is available, it is difficult to provide the microlenses 140 at the pitch L2 with this technique.

In a numerical value example of the first embodiment, the pixels 101 form a matrix of 40 rows by 40 columns. Each of the pitch L0 of the pixels 101 in the row direction and the pitch L0 of the pixels 101 in the column direction is equal to 1 μm. Each of a size of each pixel 101 in the row direction and a size of the pixel 101 in the column direction is equal to 1 μm. Here, an operation to shift the pixel electrode 130 that belongs to the fortieth column on a certain row by 0.5 μm in the outward direction relative to the pixel electrode 130 that belongs to the twenty-first column on the same row will be taken into consideration. In this case, the pitch L1 of the pixel electrodes 130 that belong to the same row is determined as follows. Specifically, a value is obtained by dividing the amount of the shift by the number of the pixels 101 from the twenty-first column to the fortieth column on the aforementioned row. Next, the obtained value is added to the pitch L0. Specifically, L1=1+0.5/20=1.025 μm is calculated. The length 1.025 μm is larger than the length 1 μm. Accordingly, when the technique for forming the pixel 101 in the sizes of 1 μm×1 μm is available, it is easy to provide the pixel electrodes 130 at the pitch L1 with this technique.

As understood from the foregoing explanation, the pixels 101 are likely to form at least one row. In an example of the first embodiment, the number of the pixels 101 that belong to a certain row is equal to J pieces. The value J is a natural number greater than or equal to 2.

Regarding the J pieces of the pixels 101, the following magnitude relationship can be established between the pitch L1 of the pixel electrodes 130 and the pitch L0 of the pixels 101, for example:

$$0.2 μm \leq ( L 1 - L 0 ) \times ( J / 2 - 1 ) \leq 2 μm .$$

To be more precise, the following magnitude relationship may be established:

$$0.2 μm \leq ( L 1 - L 0 ) \times ( J / 2 - 1 ) \leq 0.6 μm .$$

A description derived from the description of the magnitude relationship between the pitch L0 and the pitch L1 by replacing the term “row” with the term “column” and replacing the value “J” with a value “K” can also be established.

In an example, the central portion Pa includes the pixel electrode 130 extending without crossing a boundary between the microlenses 140 located adjacent to each other in a plan view. The peripheral portion Pb includes the pixel electrode 130 extending across the boundary.

In a specific example, a train of a lens group is provided across the pixels 101. The microlens 140 of each pixel 101 is a portion of the lens group. To be more precise, the microlens 140 of each pixel 101 includes a convex surface 141 that projects upward. A lower end point 142 is present between the convex surfaces 141 that are adjacent to each other. The lower end point 142 defines a boundary between the microlenses 140 located adjacent to each other.

In the first embodiment, the pitch L3 of the color filters 150 is equal to the pitch L0 of the pixels 101. The pitch L2 of the microlenses 140 is equal to the pitch L0 of the pixels 101.

Specifically, L0=L2=L3<L1 holds up in the first embodiment.

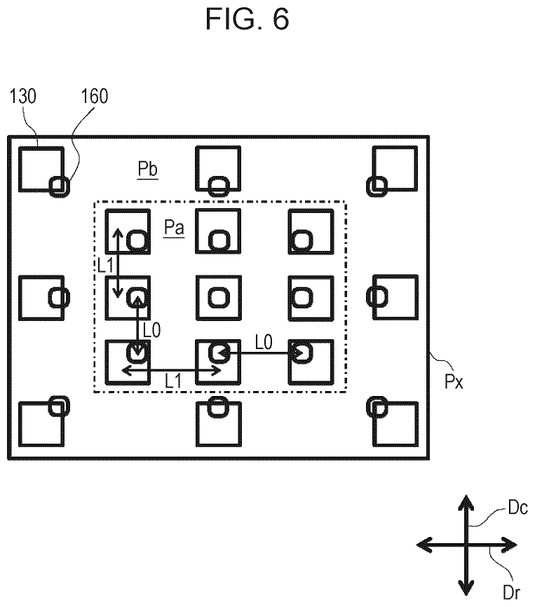

FIG. 6 is a conceptual diagram illustrating a bird's-eye view of the pixel region Px. In the example of FIG. 6, the pitch L1 of the pixel electrodes 130 is larger than the pitch L0 of the pixels 101. Accordingly, the shift of the pixel electrode 130 in the outward direction based on the pixel 101 grows larger as the pixel 101 is located more outward. As mentioned above, the outward direction is the direction from the central portion Pa toward the peripheral portion Pb.

In the example of FIG. 6, “the pitch L0 of the pixels 101” is equivalent to the pitch of the charge accumulating regions 160 to be more precise. Accordingly, “based on the pixel 101” is equivalent to “based on the charge accumulating region 160” to be more precise. Nonetheless, not only the aforementioned first definition but also any of the second to fourth definitions may also be adopted as “the pitch L0 of the pixels 101”.

In FIG. 6, a portion inside a one-dot chain line is illustrated as the central portion Pa while a portion outside the one-dot chain line is illustrated as the peripheral portion Pb for the sake of convenience. However, the one-dot chain line is not intended to restrictively interpret the boundary between the central portion Pa and the peripheral portion Pb.

In the example of FIG. 6, the pitch L0 in a row direction Dr is different from the pitch L0 in a column direction Dc. Meanwhile, the pitch L1 in the row direction Dr is different from the pitch L1 in the column direction Dc. Instead, as mentioned above, the pitch L0 in the row direction Dr may be equal to the pitch L0 in the column direction Dc. Meanwhile, the pitch L1 in the row direction Dr may be equal to the pitch L1 in the column direction Dc.

Now, several other embodiments will be described below. Elements that are common to the above-described embodiment and the following embodiments will be denoted by the same reference signs and explanations thereof may be omitted as appropriate. Moreover, explanations of the operation and effects which are common to the above-described embodiment and the following embodiments may be omitted as appropriate. Explanations concerning the respective embodiments are applicable to one another as long as there is no technical contradiction. The respective embodiments may be carried out in combination as long as there is no technical contradiction.

### Second Embodiment

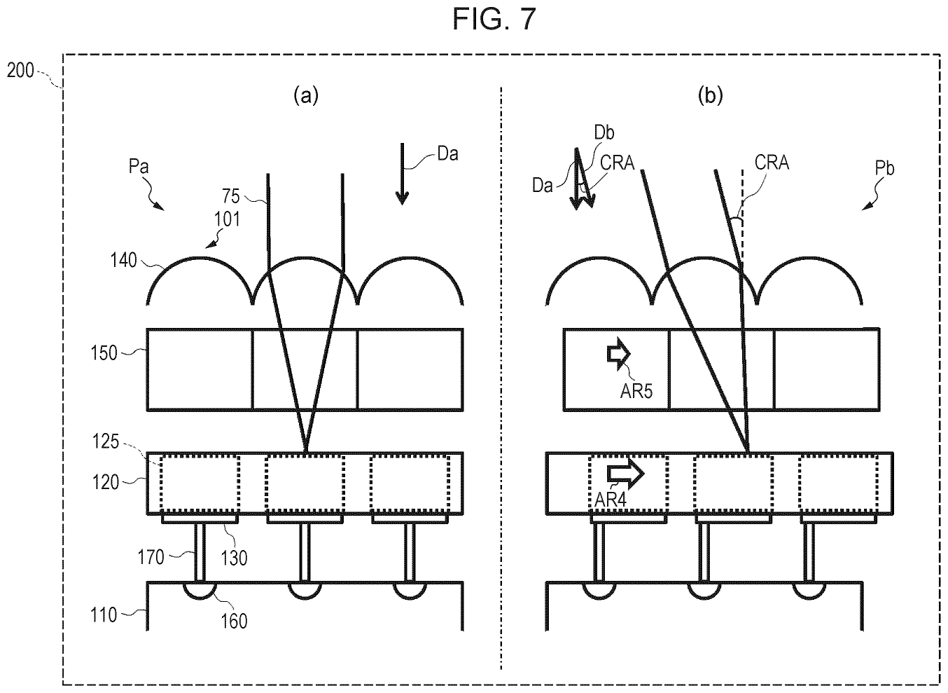

FIG. 7 illustrates schematic sectional views of an imaging device 200 according to a second embodiment.

In the second embodiment, the pitch L1 of the pixel electrodes 130 is larger than the pitch L0 of the pixels 101 as with the first embodiment. Accordingly, at the peripheral portion Pb, the pixel electrode 130 is shifted in the outward direction as compared to that at the central portion Pa. FIG. 7 schematically illustrates the shift of the pixel electrode 130 by using a fourth block arrow AR4. The pitch L2 of the microlenses 140 is equal to the pitch L0 of the pixels 101.

In the second embodiment, the pitch L3 of the color filters 150 is larger than the pitch L0 of the pixels 101 unlike the first embodiment. Accordingly, at the peripheral portion Pb, the color filter 150 is shifted in the outward direction as compared to that at the central portion Pa. FIG. 7 schematically illustrates the shift of the color filter 150 by using a fifth block arrow AR5.

In the second embodiment, the pitch L3 of the color filters 150 is smaller than the pitch L1 of the pixel electrodes 130.

Specifically, L0=L2<L3<L1 holds up in the second embodiment.

As understood from the foregoing explanation, the pixels 101 are likely to form at least one row. In an example of the second embodiment, the number of the pixels 101 that belong to a certain row is equal to J pieces. The value J is a natural number greater than or equal to 2.

Regarding the above-mentioned J pieces of the pixels 101, the following magnitude relationship can be established between the pitch L1 of the pixel electrodes 130 and the pitch L0 of the pixels 101, for example:

$$0.2 μm \leq ( L 1 - L 0 ) \times ( J / 2 - 1 ) \leq 2 μm .$$

To be more precise, the following magnitude relationship may be established:

$$0.2 μm \leq ( L 1 - L 0 ) \times ( J / 2 - 1 ) \leq 0.6 μm .$$

Regarding the above-mentioned J pieces of the pixels 101, the following magnitude relationship can be established between the pitch L3 of the color filters 150 and the pitch L0 of the pixels 101, for example:

$$0.1 μm \leq ( L 3 - L 0 ) \times ( J / 2 - 1 ) \leq 1. μm .$$

To be more precise, the following magnitude relationship may be established:

$$0.1 μm \leq ( L 3 - L 0 ) \times ( J / 2 - 1 ) \leq 0.3 μm .$$

Regarding the above-mentioned J pieces of the pixels 101, the following magnitude relationship can be established between the pitch L1 of the pixel electrodes 130 and the pitch L3 of the color filters 150, for example:

$$0.1 μm \leq ( L 1 - L 3 ) \times ( J / 2 - 1 ) \leq 1. μm .$$

To be more precise, the following magnitude relationship may be established:

$$0.1 μm \leq ( L 1 - L 3 ) \times ( J / 2 - 1 ) \leq 0.3 μm .$$

A description derived from the description of the magnitude relationship among the pitch L0, the pitch L1, and the pitch L3 by replacing the term “row” with the term “column” and replacing the value “J” with the value “K” can also be established.

### Third Embodiment

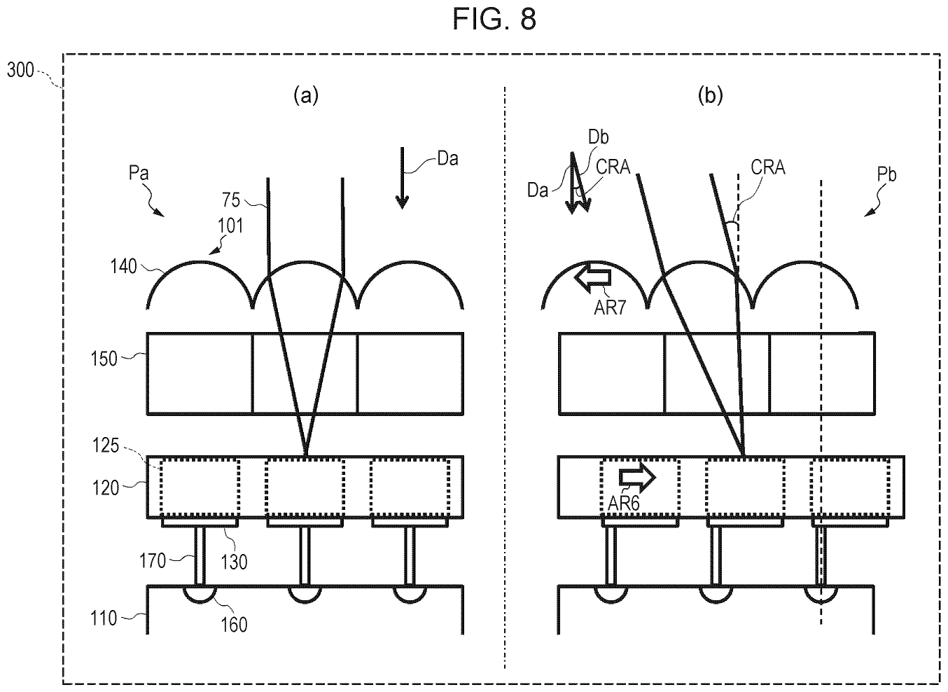

FIG. 8 illustrates schematic sectional views of an imaging device 300 according to a third embodiment.

In the third embodiment, the pitch L1 of the pixel electrodes 130 is larger than the pitch L0 of the pixels 101 as with the first embodiment. Accordingly, at the peripheral portion Pb, the pixel electrode 130 is shifted in the outward direction as compared to that at the central portion Pa. FIG. 8 schematically illustrates the shift of the pixel electrode 130 by using a sixth block arrow AR6. The pitch L3 of the color filters 150 is equal to the pitch L0 of the pixels 101.

In the third embodiment, the pitch L2 of the microlenses 140 is smaller than the pitch L0 of the pixels 101 unlike the first embodiment. Accordingly, at the peripheral portion Pb, the microlens 140 is shifted in the inward direction as compared to that at the central portion Pa. FIG. 8 schematically illustrates the shift of the microlens 140 by using a seventh block arrow AR7. As with the magnitude relationship L1>L0, the magnitude relationship L2<L0 can also contribute to the suppression of shading.

Specifically, L2<L3=L0<L1 holds up in the third embodiment.

As understood from the foregoing explanation, the pixels 101 are likely to form at least one row. In an example of the third embodiment, the number of the pixels 101 that belong to a certain row is equal to J pieces. The value J is a natural number greater than or equal to 2.

Regarding the above-mentioned J pieces of the pixels 101, the following magnitude relationship can be established between the pitch L1 of the pixel electrodes 130 and the pitch L0 of the pixels 101, for example:

$$0.1 µm \leq ( L 1 - L 0 ) \times ( J / 2 - 1 ) \leq 1 µm .$$

To be more precise, the following magnitude relationship may be established:

$$0.1 µm \leq ( L 1 - L 0 ) \times ( J / 2 - 1 ) \leq 0.3 µm .$$

Regarding the above-mentioned J pieces of the pixels 101, the following magnitude relationship can be established between the pitch L0 of the pixels 101 and the pitch L2 of the microlenses 140, for example:

$$0.1 µm \leq ( L 0 - L 2 ) \times ( J / 2 - 1 ) \leq 1 µm .$$

To be more precise, the following magnitude relationship may be established:

$$0.1 µm \leq ( L 0 - L 2 ) \times ( J / 2 - 1 ) \leq 0.3 µm .$$

Regarding the above-mentioned J pieces of the pixels 101, the following magnitude relationship can be established between the pitch L1 of the pixel electrodes 130 and the pitch L2 of the microlenses 140, for example:

$$0.2 µm \leq ( L 1 - L 2 ) \times ( J / 2 - 1 ) \leq 2 µm .$$

To be more precise, the following magnitude relationship may be established:

$$0.2 µm \leq ( L 1 - L 2 ) \times ( J / 2 - 1 ) \leq 0.6 µm .$$

A description derived from the description of the magnitude relationship among the pitch L0, the pitch L1, and the pitch L2 by replacing the term “row” with the term “column” and replacing the value “J” with the value “K” can also be established.

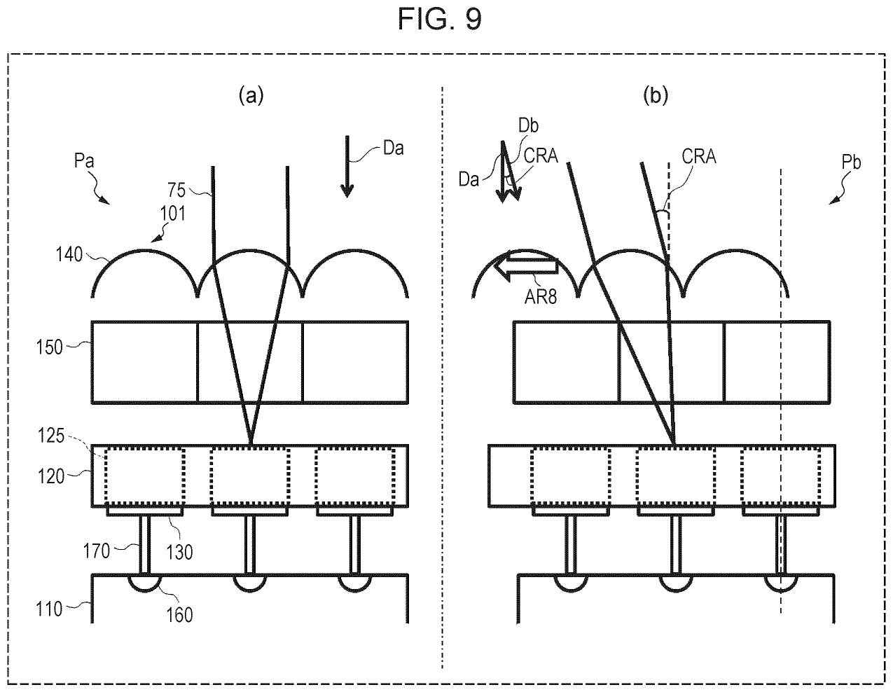

Effects of the third embodiment will be described below with reference to FIG. 9. FIG. 9 illustrates schematic sectional views of an imaging device according to a third reference mode.

As illustrated in FIG. 9, in the third reference mode, the pitch L2 of the microlenses 140 is smaller than the pitch L0 of the pixels 101 as with the third embodiment. Accordingly, at the peripheral portion Pb, the microlens 140 is shifted in the inward direction as compared to that at the central portion Pa. FIG. 9 schematically illustrates the shift of the microlens 140 by using an eighth block arrow AR8. Meanwhile, in the third reference mode, the pitch L1 of the pixel electrodes 130 is equal to the pitch L0 of the pixels 101 unlike the third embodiment. For this reason, suppression of shading by using the magnitude relationship L1>L0 does not take place in the third reference mode. Accordingly, as compared to the third embodiment, it is necessary to increase contribution of the magnitude relationship L2<L0 to the suppression of shading in the third reference mode. This means that a difference obtained by subtracting L2 from L0 needs to be increased in the third reference mode in order to achieve the same level of the suppression of shading as that of the third embodiment. To be more precise, this means that the pitch L2 needs to be reduced as compared to that of the third embodiment so as to increase the amount of shift of the microlens 140 in the inward direction at the peripheral portion Pb in order to achieve the above-mentioned suppression. This configuration is not suitable for reducing the necessity of the technique development for microfabrication.

On the other hand, the third embodiment establishes not only the magnitude relationship L2<L0 but also the magnitude relationship L1>L0 as described above. Accordingly, in the third embodiment, it is likely that shading is suppressed without increasing the difference obtained by subtracting L2 from L0 as compared to the third reference mode. Hence, the third embodiment is suitable to suppress shading while reducing the necessity of the technique development for microfabrication.

### Fourth Embodiment

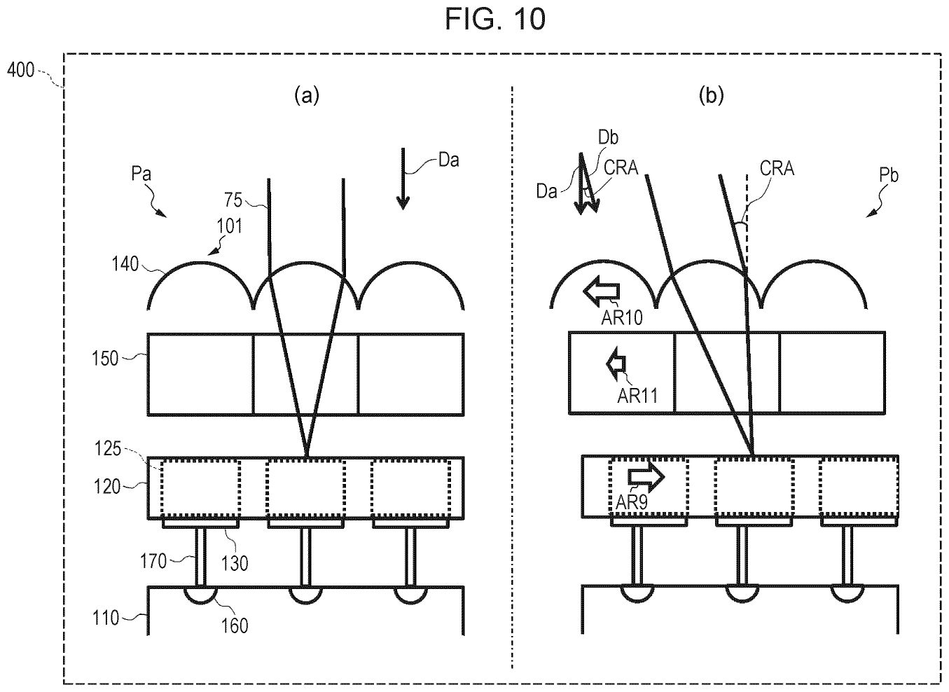

FIG. 10 illustrates schematic sectional views of an imaging device 400 according to a fourth embodiment.

In the fourth embodiment, the pitch L1 of the pixel electrodes 130 is larger than the pitch L0 of the pixels 101 as with the third embodiment. Accordingly, at the peripheral portion Pb, the pixel electrode 130 is shifted in the outward direction as compared to that at the central portion Pa. FIG. 10 schematically illustrates the shift of the pixel electrode 130 by using a ninth block arrow AR9. The pitch L2 of the microlenses 140 is smaller than the pitch L0 of the pixels 101. Accordingly, at the peripheral portion Pb, the microlens 140 is shifted in the inward direction as compared to that at the central portion Pa. FIG. 10 schematically illustrates the shift of the microlens 140 by using a tenth block arrow AR10.

In the fourth embodiment, the pitch L3 of the color filters 150 is smaller than the pitch L0 of the pixels 101 unlike the third embodiment. Accordingly, at the peripheral portion Pb, the color filter 150 is shifted in the inward direction as compared to that at the central portion Pa. FIG. 10 schematically illustrates the shift of the color filter 150 by using an eleventh block arrow AR11.

To be more precise, in the fourth embodiment, the pitch L2 of the microlenses 140 is smaller than the pitch L3 of the color filters 150. Accordingly, the amount of shift in the inward direction of the microlens 140 at the peripheral portion Pb is larger than the amount of shift in the inward direction of the color filter 150 at the peripheral portion Pb.

Specifically, L2<L3<L0<L1 holds up in the fourth embodiment.

In the fourth embodiment, the microlens 140, the color filter 150, and the photoelectric conversion region 125 are disposed in a direction close to the oblique direction Db at the peripheral portion Pb as compared to those of the first reference mode illustrated in FIG. 4. A light condensing line is formed between the microlens 140 and the photoelectric conversion region 125, and the color filter 150 is disposed at a position where the light condensing line passes through. Here, the light condensing line is a line indicating the light 75 that is directed to the photoelectric conversion region 125 while converging after the passage through the microlens 140.

As understood from the foregoing explanation, the pixels 101 are likely to form at least one row. In an example of the fourth embodiment, the number of the pixels 101 that belong to a certain row is equal to J pieces. The value J is a natural number greater than or equal to 2.

Regarding the above-mentioned J pieces of the pixels 101, the following magnitude relationship can be established between the pitch L1 of the pixel electrodes 130 and the pitch L0 of the pixels 101, for example:

$$0.1 µm \leq ( L 1 - L 0 ) \times ( J / 2 - 1 ) \leq 1 µm .$$

To be more precise, the following magnitude relationship may be established:

$$0.1 µm \leq ( L 1 - L 0 ) \times ( J / 2 - 1 ) \leq 0.3 µm .$$

Regarding the above-mentioned J pieces of the pixels 101, the following magnitude relationship can be established between the pitch L0 of the pixels 101 and the pitch L2 of the microlenses 140, for example:

$$0.1 µm \leq ( L 0 - L 2 ) \times ( J / 2 - 1 ) \leq 1 µm .$$

To be more precise, the following magnitude relationship may be established:

$$0.1 µm \leq ( L 0 - L 2 ) \times ( J / 2 - 1 ) \leq 0.3 µm .$$

Regarding the above-mentioned J pieces of the pixels 101, the following magnitude relationship can be established between the pitch L0 of the pixels 101 and the pitch L3 of the color filters 150, for example:

$$0.05 µm \leq ( L 0 - L 3 ) \times ( J / 2 - 1 ) \leq 0.5 µm .$$

To be more precise, the following magnitude relationship may be established:

$$0.05 µm \leq ( L 0 - L 3 ) \times ( J / 2 - 1 ) \leq 0.15 µm .$$

Regarding the above-mentioned J pieces of the pixels 101, the following magnitude relationship can be established between the pitch L1 of the pixel electrodes 130 and the pitch L2 of the microlenses 140, for example:

$$0.2 µm \leq ( L 1 - L 2 ) \times ( J / 2 - 1 ) \leq 2 µm .$$

To be more precise, the following magnitude relationship may be established:

$$0.2 µm \leq ( L 1 - L 2 ) \times ( J / 2 - 1 ) \leq 0.6 µm .$$

Regarding the above-mentioned J pieces of the pixels 101, the following magnitude relationship can be established between the pitch L1 of the pixel electrodes 130 and the pitch L3 of the color filters 150, for example:

$$0.15 µm \leq ( L 1 - L 3 ) \times ( J / 2 - 1 ) \leq 1.5 µm .$$

To be more precise, the following magnitude relationship may be established:

$$0.15 µm \leq ( L 1 - L 3 ) \times ( J / 2 - 1 ) \leq 0.45 µm .$$

Regarding the above-mentioned J pieces of the pixels 101, the following magnitude relationship can be established between the pitch L3 of the color filters 150 and the pitch L2 of the microlenses 140, for example:

$$0.05 µm \leq ( L 3 - L 2 ) \times ( J / 2 - 1 ) \leq 0.5 µm .$$

To be more precise, the following magnitude relationship may be established:

$$0.05 µm \leq ( L 3 - L 2 ) \times ( J / 2 - 1 ) \leq 0.15 µm$$

A description derived from the description of the magnitude relationship among the pitch L0, the pitch L1, the pitch L2, and the pitch L3 by replacing the term “row” with the term “column” and replacing the value “J” with the value “K” can also be established.

### Fifth Embodiment

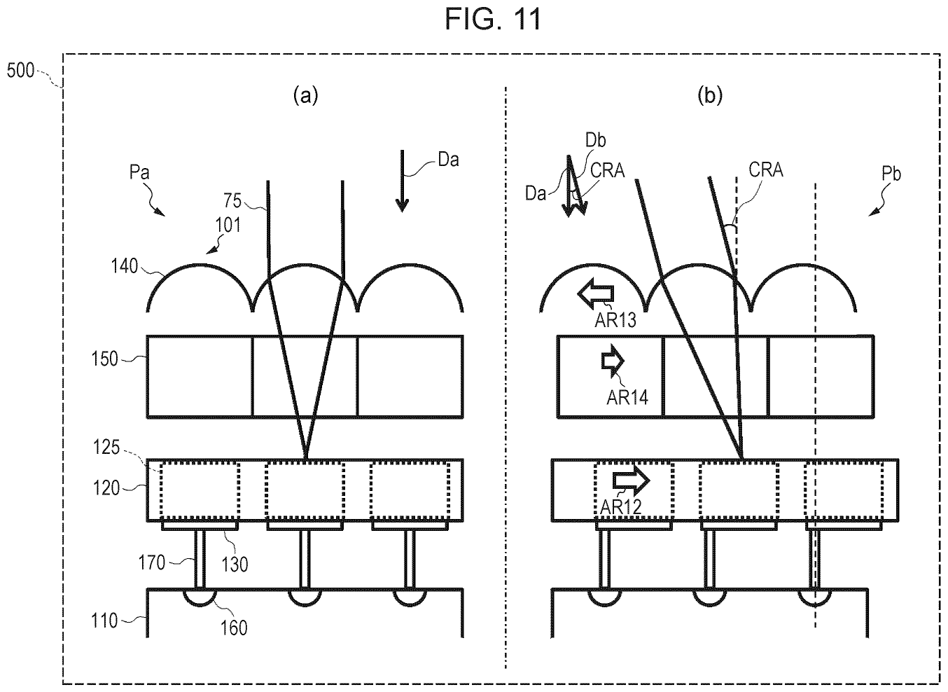

FIG. 11 illustrates schematic sectional views of an imaging device 500 according to a fifth embodiment.

In the fifth embodiment, the pitch L1 of the pixel electrodes 130 is larger than the pitch L0 of the pixels 101 as with the fourth embodiment. Accordingly, at the peripheral portion Pb, the pixel electrode 130 is shifted in the outward direction as compared to that at the central portion Pa. FIG. 11 schematically illustrates the shift of the pixel electrode 130 by using a twelfth block arrow AR12. The pitch L2 of the microlenses 140 is smaller than the pitch L0 of the pixels 101. Accordingly, at the peripheral portion Pb, the microlens 140 is shifted in the inward direction as compared to that at the central portion Pa. FIG. 11 schematically illustrates the shift of the microlens 140 by using a thirteenth block arrow AR13.

In the fifth embodiment, the pitch L3 of the color filters 150 is larger than the pitch L0 of the pixels 101 unlike the fourth embodiment. Accordingly, at the peripheral portion Pb, the color filter 150 is shifted in the outward direction as compared to that at the central portion Pa. FIG. 11 schematically illustrates the shift of the color filter 150 by using a fourteenth block arrow AR14.

In the fifth embodiment, the pitch L3 of the color filters 150 is smaller than the pitch L1 of the pixel electrodes 130. Accordingly, the amount of shift in the outward direction of the color filter 150 at the peripheral portion Pb is smaller than the amount of shift in the outward direction of the pixel electrode 130 at the peripheral portion Pb.

Specifically, L2<L0<L3<L1 holds up in the fifth embodiment.

As understood from the foregoing explanation, the pixels 101 are likely to form at least one row. In an example of the fifth embodiment, the number of the pixels 101 that belong to a certain row is equal to J pieces. The value J is a natural number greater than or equal to 2.

Regarding the above-mentioned J pieces of the pixels 101, the following magnitude relationship can be established between the pitch L1 of the pixel electrodes 130 and the pitch L0 of the pixels 101, for example:

$$0.1 µm \leq ( L 1 - L 0 ) \times ( J / 2 - 1 ) \leq 1 µm .$$

To be more precise, the following magnitude relationship may be established:

$$0.1 µm \leq ( L 1 - L 0 ) \times ( J / 2 - 1 ) \leq 0.3 µm .$$

Regarding the above-mentioned J pieces of the pixels 101, the following magnitude relationship can be established between the pitch L0 of the pixels 101 and the pitch L2 of the microlenses 140, for example:

$$0.1 µm \leq ( L 0 - L 2 ) \times ( J / 2 - 1 ) \leq 1 µm .$$

To be more precise, the following magnitude relationship may be established:

$$0.1 µm \leq ( L 0 - L 2 ) \times ( J / 2 - 1 ) \leq 0.3 µm .$$

Regarding the above-mentioned J pieces of the pixels 101, the following magnitude relationship can be established between the pitch L3 of the color filters 150 and the pitch L0 of the pixels 101, for example:

$$0.05 µm \leq ( L 3 - L 0 ) \times ( J / 2 - 1 ) \leq 0.5 µm .$$

To be more precise, the following magnitude relationship may be established:

$$0.05 µm \leq ( L 3 - L 0 ) \times ( J / 2 - 1 ) \leq 0.15 µm .$$

Regarding the above-mentioned J pieces of the pixels 101, the following magnitude relationship can be established between the pitch L1 of the pixel electrodes 130 and the pitch L2 of the microlenses 140, for example:

$$0.1 µm \leq ( L 1 - L 2 ) \times ( J / 2 - 1 ) \leq 1 µm .$$

To be more precise, the following magnitude relationship may be established:

$$0.1 µm ( L 1 - L 2 ) \times ( J / 2 - 1 ) \leq 0.3 µm .$$

Regarding the above-mentioned J pieces of the pixels 101, the following magnitude relationship can be established between the pitch L1 of the pixel electrodes 130 and the pitch L3 of the color filters 150, for example:

$$0.05 µm \leq ( L 1 - L 3 ) \times ( J / 2 - 1 ) \leq 0.5 µm .$$

To be more precise, the following magnitude relationship may be established:

$$0.05 µm \leq ( L 1 - L 3 ) \times ( J / 2 - 1 ) \leq 0.15 µm .$$

Regarding the above-mentioned J pieces of the pixels 101, the following magnitude relationship can be established between the pitch L3 of the color filters 150 and the pitch L2 of the microlenses 140, for example:

$$0.15 µm \leq ( L 3 - L 2 ) \times ( J / 2 - 1 ) \leq 1.5 µm .$$

To be more precise, the following magnitude relationship may be established:

$$0.15 µm \leq ( L 3 - L 2 ) \times ( J / 2 - 1 ) \leq 0.45 µm .$$

A description derived from the description of the magnitude relationship among the pitch L0, the pitch L1, the pitch L2, and the pitch L3 by replacing the term “row” with the term “column” and replacing the value “J” with the value “K” can also be established.

Here, a difference obtained by subtracting the pitch L0 from the pitch L1 will be defined as a first difference. A difference obtained by subtracting the pitch L2 from the pitch L0 will be defined as a second difference. A difference obtained by subtracting the pitch L3 from the pitch L0 will be defined as a third difference. The first difference is a positive value. The second difference is any of a positive value, a negative value, and zero. The third difference is any of a positive value, a negative value, and zero.

As long as there is no contradiction, at least one selected from the group consisting of the following magnitude relationships (a) to (i) may be applied to any of the first to the fifth embodiments:
(a) The first difference is equal to the second difference;
(b) The first difference is larger than the second difference;
(c) The first difference is smaller than the second difference;
(d) The first difference is equal to the third difference;
(e) The first difference is larger than the third difference;
(f) The first difference is smaller than the third difference;
(g) The second difference is equal to the third difference;
(h) The second difference is larger than the third difference; and
(i) The second difference is smaller than the third difference.

For example, the magnitude relationship (f), that is, the first difference<the third difference is suitable for reducing the necessity of the technique development for microfabrication.

### Sixth Embodiment

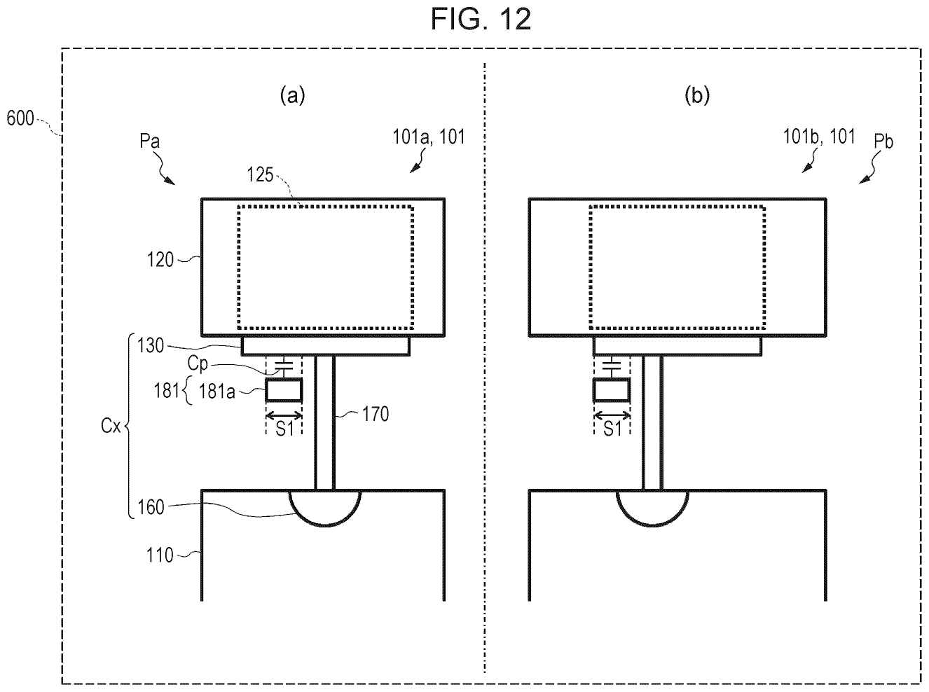

FIG. 12 illustrates schematic sectional views of an imaging device 600 according to a sixth embodiment.

In the sixth embodiment, L0=L2=L3<L1 holds up as with the first embodiment.

In the sixth embodiment, the first wiring layer 181 includes a first wire 181a. A parasitic capacitance Cp may be generated between the pixel electrode 130 and the first wire 181a due to coupling between the pixel electrode 130 and the first wire 181a.

The first electric pathway 170 electrically connects the pixel electrode 130 and the charge accumulating region 160.

A charge accumulation capacitance Cx is formed in each pixel 101. The charge accumulation capacitance Cx is the entire capacitance that accumulates the electric charges generated by the photoelectric conversion in the photoelectric conversion layer 120. The charge accumulation capacitance Cx includes the pixel electrode 130, the charge accumulating region 160, and the first electric pathway 170. These features also apply to the previous embodiments. In the meantime, the charge accumulation capacitance Cx includes the parasitic capacitance Cp.

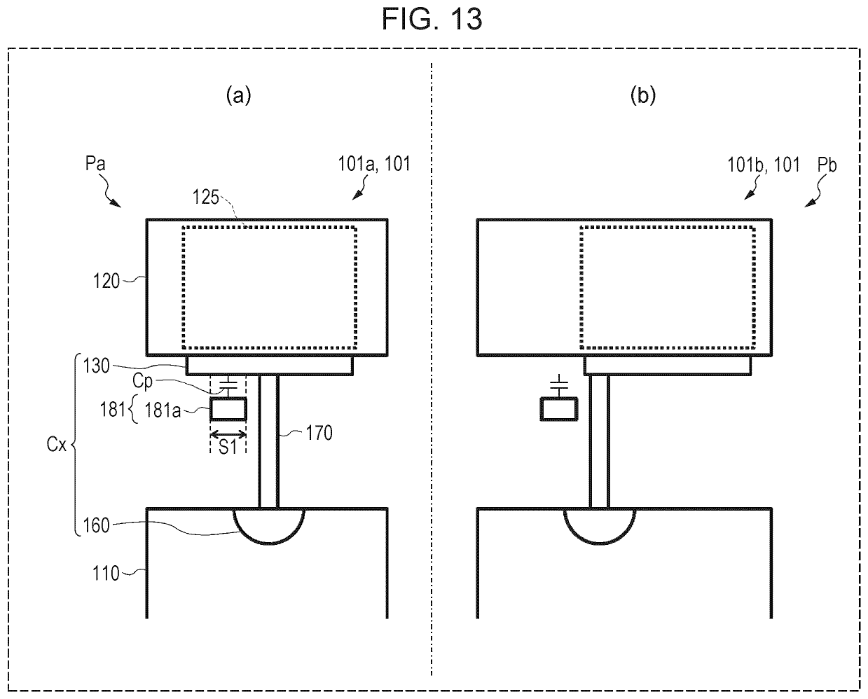

Effects of the sixth embodiment will be described below with reference to FIG. 13. FIG. 13 illustrates schematic sectional views of an imaging device according to a fourth reference mode.

In the fourth reference mode illustrated in FIG. 13, L0=L2=L3<L1 holds up as with the first embodiment.

As illustrated in Portion (a) of FIG. 13, the first wire 181a overlaps the pixel electrode 130 in a plan view at the central portion Pa. The parasitic capacitance Cp is therefore large.

The pitch L1 of the pixel electrodes 130 is larger than the pitch L0 of the pixels 101. Accordingly, at the peripheral portion Pb, the pixel electrode 130 is shifted in the outward direction as compared to that at the central portion Pa. For this reason, the first wire 181a does not overlap the pixel electrode 130 in a plan view at the peripheral portion Pb as illustrated in Portion (b) of FIG. 13. The parasitic capacitance Cp is therefore small.

Due to the aforementioned reasons, in the fourth reference mode, the parasitic capacitance Cp of the pixel 101 at the peripheral portion Pb is smaller than the parasitic capacitance Cp of the pixel 101 at the central portion Pa. Accordingly, the charge accumulation capacitance Cx of the pixel 101 at the peripheral portion Pb is smaller than the charge accumulation capacitance Cx of the pixel 101 at the central portion Pa. As a consequence, characteristics of the pixel 101 at the central portion Pa and the characteristics of the pixel 101 at the peripheral portion Pb may vary.

On the other hand, in the sixth embodiment illustrated in FIG. 12, the first wire 181a overlaps the pixel electrode 130 in a plan view not only at the central portion Pa but also at the peripheral portion Pb. To be more precise, the pitch L1 of the pixel electrodes 130, the size of the pixel electrodes 130 in a plan view, and the like are determined in order to bring about this overlap. Accordingly, it is possible to suppress the variation between the characteristics of the pixel 101 at the central portion Pa and the characteristics of the pixel 101 at the peripheral portion Pb even when L1>L0 holds up.

As understood from the foregoing explanation, it is likely that the first wiring layer 181 is opposed to the pixel electrode 130. Now, the expression “the first wiring layer 181 is opposed to the pixel electrode 130” will be described. This expression is an expression of an intention of encompassing a mode in which the imaging device 600 includes the wiring layers 180, that the wiring layers 180 includes the first wiring layers 181, and that the first wiring layer 181 is the wiring layer among the wiring layers 180 which is located closest to the pixel electrode 130. This expression is an expression of an intention of encompassing a mode in which the number of wiring layers included in the imaging device 600 is one layer and the one wiring layer is the first wiring layer 181.

As described above, the charge accumulation capacitance Cx includes the parasitic capacitance Cp. In a more generalized description, the charge accumulation capacitance Cx may include the parasitic capacitance between the pixel electrode 130 and the first wiring layer 181.

A pixel 101 located at the central portion Pa of the pixel region Px will be hereinafter referred to as a central pixel 101a. A pixel 101 located at the peripheral portion Pb of the pixel region Px will be hereinafter referred to as a peripheral pixel 101b. An area of overlap between the pixel electrode 130 and the first wiring layer 181 in a plan view will be referred to as a first overlapping area S1. Here, a portion where the first wire 181a overlaps the pixel electrode 130 in a plan view is indicated with “S1” in FIG. 13 for the sake of convenience. However, when the first wiring layer 181 includes an element other than the first wire 181a, the element may also be involved in the first overlapping area S1.

In the sixth embodiment, the first overlapping area S1 of the central pixel 101a is equal to the first overlapping area S1 of the peripheral pixel 101b. This configuration can suppress the variation of the parasitic capacitance between the pixel electrode 130 and the first wiring layer 181 in the central pixel 101a relative to the parasitic capacitance between the pixel electrode 130 and the first wiring layer 181 in the peripheral pixel 101b. Thus, this configuration can suppress the variation between the charge accumulation capacitance Cx in the central pixel 101a and the charge accumulation capacitance Cx in the peripheral pixel 101b. As a consequence, the variation between the characteristics of the central pixel 101a and the characteristics of the peripheral pixel 101b can be suppressed.

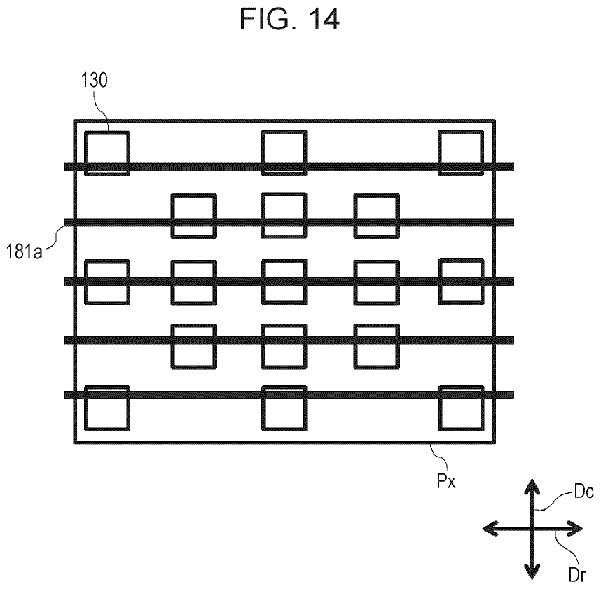

FIG. 14 is a schematic plan view of the imaging device 600 according to the sixth embodiment. In the example of FIG. 14, the imaging device 600 includes the first wires 181a. The pixels 101 are arrayed to form rows and columns. Here, (viii) the pitch L1 of the pixel electrodes 130 is larger than the pitch L0 of the pixels 101 regarding each of the columns. The first wires 181a extend in the row direction Dr in such a way as to be arranged at a regular pitch in the column direction Dc. Each of the first wires 181a is correlated with one of the rows. In a plan view, the pixel electrode 130 in each of the pixels 101 overlaps the first wire 181a correlated with the row to which the relevant pixel 101 belongs. In each of the pixels 101, this overlap in a plan view may be formed across the entire line width of the first wire 181a.

In addition, in the example of FIG. 14 to be more precise, (vii) the pitch L1 of the pixel electrodes 130 is larger than the pitch L0 of the pixels 101 regarding each of the rows.

### Seventh Embodiment

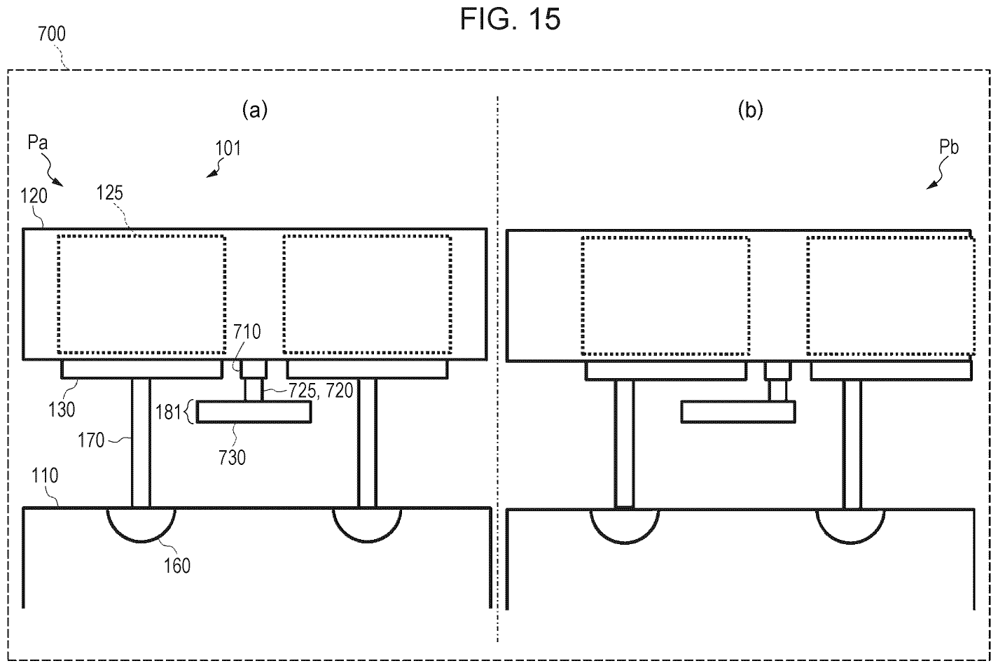

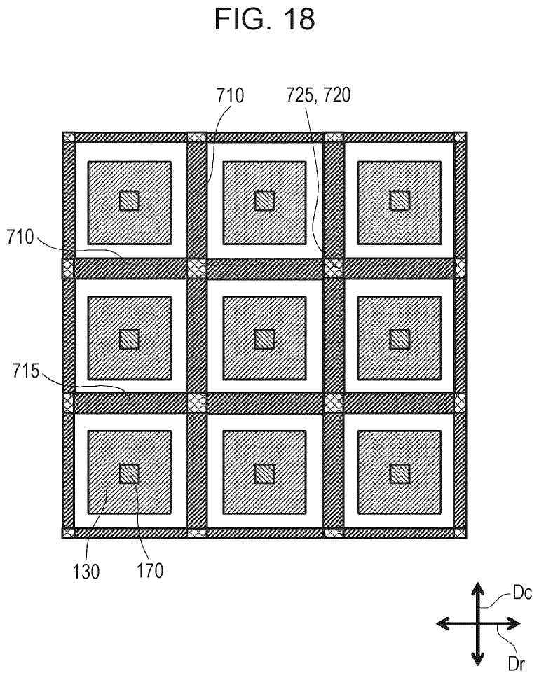

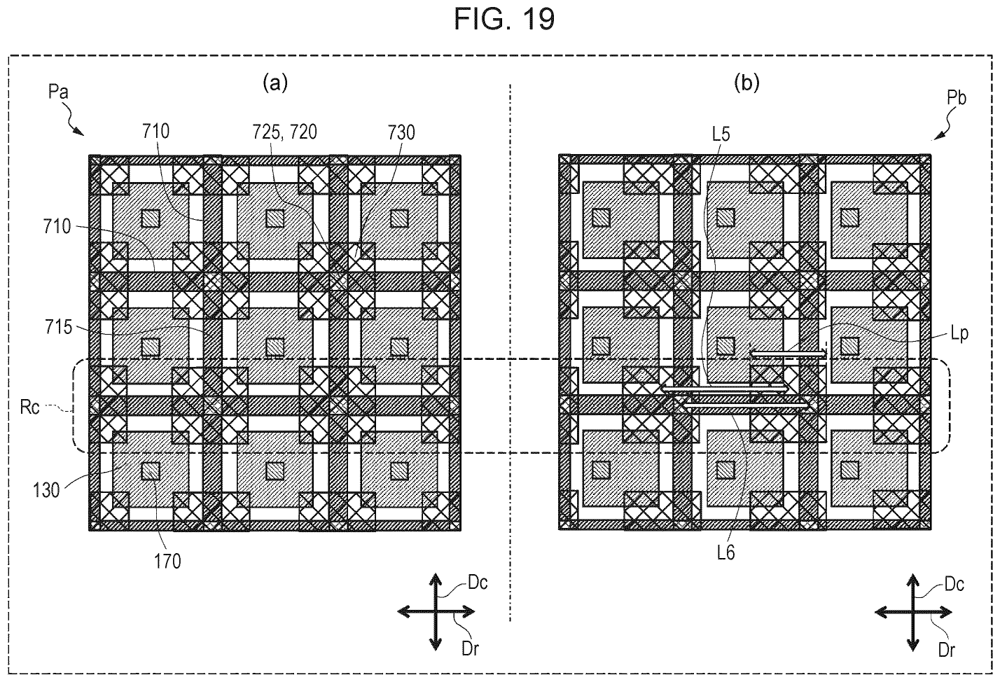

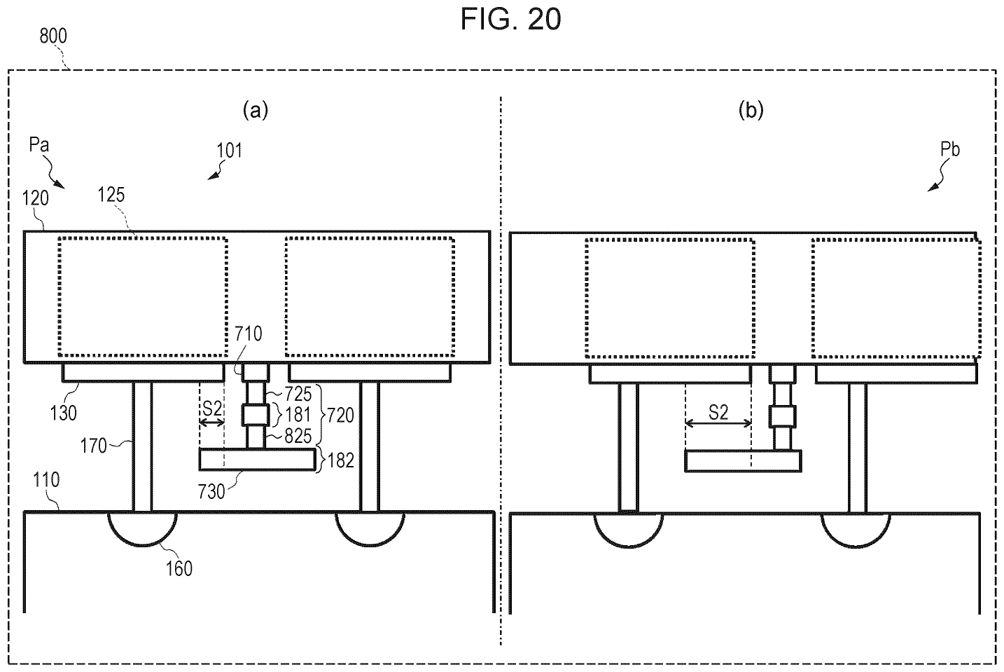

FIG. 15 illustrates schematic explanatory diagrams of an imaging device 700 according to a seventh embodiment. For the sake of convenience of explanation, FIG. 15 depicts sectional structures of the pixel electrodes 130, the first electric pathways 170, the charge accumulating regions 160, a separated electrode 710, a second electric pathway 720, a pad 730, and the like. However, as will be understood from FIGS. 18 and 19 to be described below, all of these element do not always have to be present on the same section in reality. This feature also applies to FIG. 20 to be described below.

In the seventh embodiment, L0=L2=L3<L1 holds up as with the first embodiment.

The imaging device 700 includes the separated electrodes 710, the second electric pathways 720, and the pads 730. Each separated electrode 710 may also be referred to as a shield electrode. In the seventh embodiment, each second electric pathway 720 is a first separated via 725. Each pad 730 is included in the first wiring layer 181.

Each of the separated electrodes 710, the corresponding second electric pathway 720 out of the second electric pathways 720, and the corresponding pad 730 out of the pads 730 are electrically connected in this order. Meanwhile, each of the separated electrodes 710, the corresponding second electric pathway 720 out of the second electric pathways 720, and the corresponding pad 730 out of the pads 730 are physically connected in this order.

Each of the separated electrodes 710 is disposed between two pixel electrodes 130, which are located adjacent to each other, in such a way as to be electrically separated from the two pixel electrodes 130. Each of the separated electrodes 710 is disposed between the two pixel electrodes 130, which are located adjacent to each other, and are located away from the two pixel electrodes 130. As described above, the photoelectric conversion layer 120 has the region which is deviated from the photoelectric conversion region 125. The separated electrode 710 collects the electric charges generated by photoelectric conversion in this deviated region. The collected electric charges are discharged while passing through the second electric pathway 720 and the pad 730 in this order. Thus, the separated electrode 710 can suppress noise contamination in the charge accumulating region 160.

The separated electrode 710 is located below the photoelectric conversion layer 120. That is to say, the separated electrode 710 is located on the same side as the pixel electrode 130 when viewed from the photoelectric conversion layer 120. Meanwhile, the separated electrode 710 is located between the pixel electrode 130 and the pixel electrode 130 being adjacent to each other. To be more precise, the separated electrode 710 spreads across a boundary between the pixel 101 and the pixel 101 being adjacent to each other.

The separated electrode 710 contains at least one of a metal or a metal compound. Examples of the metal to be contained in the separated electrode 710 include titanium, tantalum, and the like. Examples of the metal compound to be contained in the separated electrode 710 include a metal nitride. To be more precise, examples of the metal compound to be contained in the separated electrode 710 include titanium nitride, tantalum nitride, and the like. Each of the titanium, tantalum, titanium nitride, and tantalum nitride is opaque. However, the separated electrode 710 may contain a transparent material such as ITO. The material of the separated electrode 710 may be the same as or different from the material of the pixel electrode 130.

Examples of a material of the second electric pathway 720 include a metal, a metal compound, a semiconductor, and the like. The material of the second electric pathway 720 may be the same as or different from the material of the first electric pathway 170.

A material of the first separated via 725 is any of a metal, a metal compound, and the like. The metal is any of copper, tungsten, cobalt, and the like. For example, the metal compound is any of a metal nitride, a metal oxide, and the like. The first separated via 725 may be formed from polycrystalline silicon provided with conductivity. The material of the first separated via 725 may be the same as or different from the material of the first via 171. These features also apply to the pad 730.

In the seventh embodiment, the pad 730 has a lump form. Typically, the pad 730 has the lump form in a uniform thickness and a membrane shape.

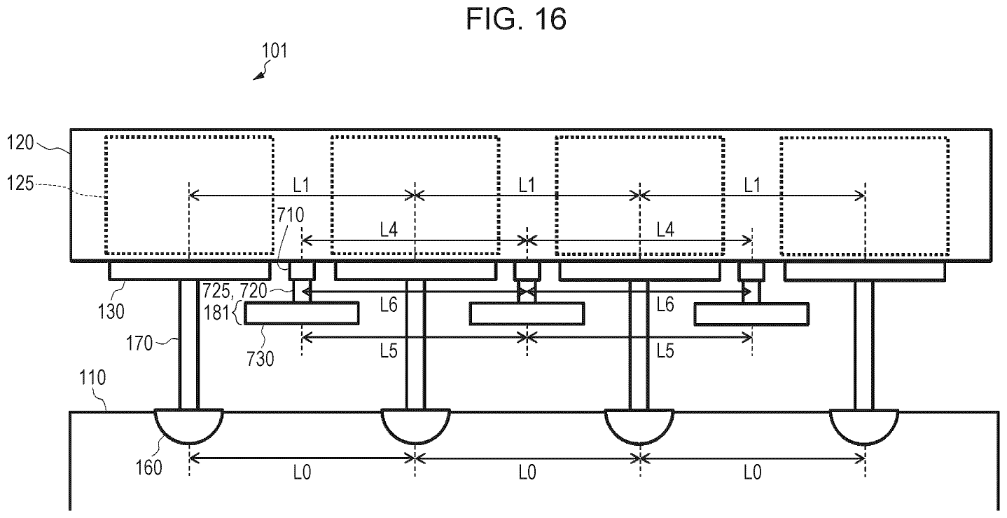

FIG. 16 is an explanatory diagram of the pitches. FIG. 16 illustrates the pitch L0 of the pixels 101, the pitch L1 of the pixel electrodes 130, a pitch L4 of the separated electrodes 710, a pitch L5 of the pads 730, and a pitch L6 of the second electric pathways 720.

In the seventh embodiment, the pitch L4 of the separated electrodes 710 is different from the pitch L5 of the pads 730. The pitch L6 of the second electric pathways 720 is different from the pitch L5 of the pads 730.

To be more precise, the pitch L4 of the separated electrodes 710 and the pitch L6 of the second electric pathways 720 are equal to the pitch L1 of the pixel electrodes 130. The pitch L5 of the pads 730 is equal to the pitch L0 of the pixels 101. Moreover, as described above, the pitch L1 of the pixel electrodes 130 is larger than the pitch L0 of the pixels 101. Accordingly, the pitch L4 and the pitch L6 are larger than the pitch L5.

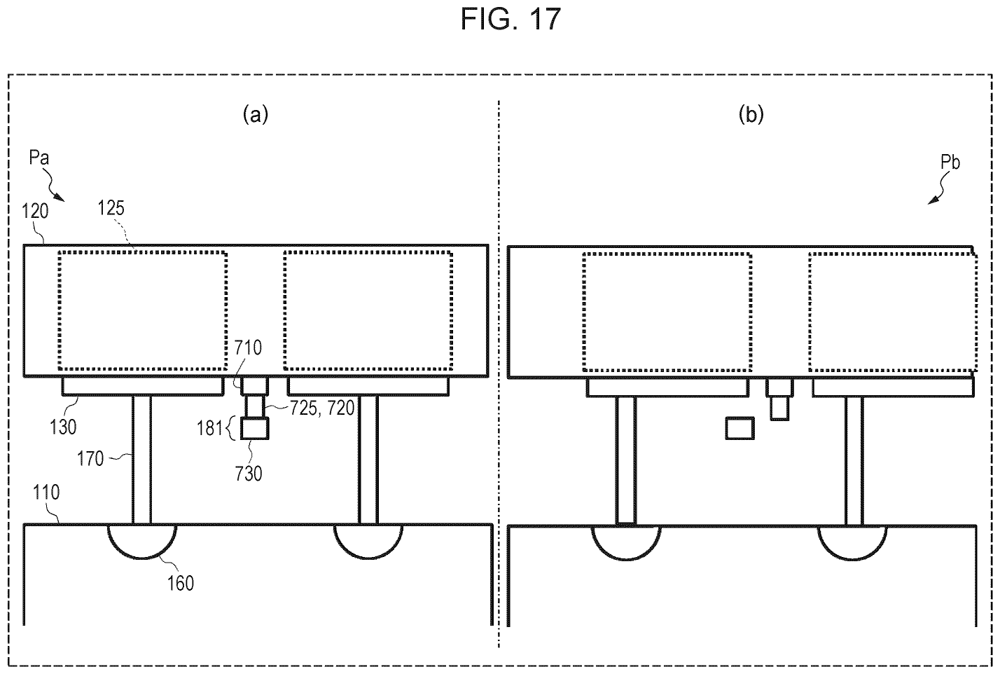

Effects of the seventh embodiment will be described below with reference to FIG. 17. FIG. 17 illustrates schematic sectional views of an imaging device according to a fifth reference mode.

As illustrated in FIG. 17, in the fifth reference mode, the area of the pad 730 in a plan view is small as compared to that of the seventh embodiment.

As illustrated in Portion (a) of FIG. 17, at the central portion Pa, the separated electrode 710, the second electric pathway 720, and the pad 730 are electrically and physically connected in this order.

The pitch L5 of the pads 730 is different from the pitch L4 of the separated electrodes 710 and the pitch L6 of the second electric pathways 720. Accordingly, positional relationships among the pad 730, the separated electrode 710, and the second electric pathway 720 are different between the central portion Pa and the peripheral portion Pb. For this reason, as illustrated in Portion (b) of FIG. 17, the pad 730 does not overlap the separated electrode 710 and the second electric pathway 720 in a plan view at the peripheral portion Pb. As a consequence, the second electric pathway 720 is neither electrically nor physically connected to the pad 730 at the peripheral portion Pb.

On the other hand, in the seventh embodiment illustrated in FIG. 15, each of the separated electrodes 710 overlaps the corresponding pad 730 out of the pads 730 in a plan view. Accordingly, it is easy to avoid the occurrence of a region where the separated electrode 710 and the pad 730 cannot be electrically connected by the second electric pathway 720. Accordingly, it is easy to avoid the occurrence of a region where the separated electrode 710 and the pad 730 cannot be electrically connected by the second electric pathway 720 not only at the central portion Pa but also at the peripheral portion Pb.

To be more precise, in the seventh embodiment, the sizes of the pads 730 are determined such that each of the separated electrodes 710 overlaps the corresponding pad 730 out of the pads 730 in a plan view.

FIG. 18 is a schematic plan view for explaining the separated electrodes 710 according to the seventh embodiment.

In the example illustrated in FIG. 18, the imaging device 700 includes a separation structure 715 in a lattice form in a plan view. The second electric pathways 720 are connected to respective intersections of the lattice form. Each of the separated electrodes 710 extends in such a way as to connect two intersections located adjacent to each other in a plan view. The separated electrodes 710 are included in the separation structure 715. The separation structure 715 is also referred to as a shield structure. The separated electrodes 710 are electrically connected to one another. To be more precise, in the example of FIG. 18, each of the separated electrodes 710 is an electrode of which a longitudinal direction is in aligned with the row direction Dr or the column direction Dc.

FIG. 19 illustrates schematic diagrams for explaining the pads 730 according to the seventh embodiment. FIG. 19 is drawn by providing FIG. 18 with hatching that represents the pads 730. In the example of FIG. 19, the pads 730 are arrayed to form rows and columns.

As illustrated in Portion (a) of FIG. 19, at the central portion Pa, the second electric pathway 720 is connected in the vicinity of the center of the pad 730 in a plan view. As illustrated in Portion (b) of FIG. 19, at the peripheral portion Pb, the second electric pathway 720 is connected to a position displaced in the outward direction from the center of the pad 730 in a plan view as compared to the central portion Pa.

In an example, of the pads 730, the number of the pads 730 that belong to a specific row Rc is equal to N pieces. The value N is a natural number greater than or equal to 2. On this specific row Rc, the N pieces of the pads 730 are arranged in the row direction Dr at the pitch L5. Moreover, on this specific row Rc, the second electric pathways 720 are arranged at the pitch L6. The pitch L6 is larger than the pitch L5. A size Lp in the row direction Dr of each of the N pieces of the pads 730 is greater than or equal to a product of a difference obtained by subtracting L5 from L6 and a difference obtained by subtracting 1 from N/2. That is to say, Lp>(L6−L5)×(N/2−1) holds up. Here, Lp>(L6−L5)×(N/2−1) may be used instead. An upper limit of the size Lp is set as appropriate. In an example, a wire is included in a wiring layer that includes the pad 730. In the wiring layer, the pad 730 is segregated from the wire. To be more precise, the size of the pad 730 may be determined so as to realize this segregation. In the seventh embodiment, the wiring layer is the first wiring layer 181.

A description derived from the above-described magnitude relationship concerning the pitch L5 and the pitch L6 by replacing the term “row” with the term “column” can also be established.

### Eighth Embodiment

FIG. 20 illustrates schematic explanatory diagrams of an imaging device 800 according to an eighth embodiment. The eighth embodiment will discuss different features from those of the seventh embodiment.

In the eighth embodiment, each second electric pathway 720 includes the first separated via 725, a portion of the first wiring layer 181, and a second separated via 825. The first separated via 725, the portion of the first wiring layer 181, and the second separated via 825 are electrically connected in this order.

In the eighth embodiment, the pad 730 is included in the second wiring layer 182.

An area of overlap between the pixel electrode 130 and the pad 730 in a plan view will be hereinafter referred to as a second overlapping area S2. In the eighth embodiment, the pitch L1 of the pixel electrodes 130 is different from the pitch L5 of the pads 730. The difference in pitch is likely to change the second overlapping area S2. However, in the eighth embodiment, the pad 730 is included in the second wiring layer 182 that is relatively far from the pad 730 instead of the first wiring layer 181 that is relatively close to the pad 730. For this reason, coupling between the pixel electrode 130 and the pad 730 is limited even in the region where the pixel electrode 130 overlaps the pad 730 in a plan view. As a consequence, it is possible to suppress the variation in characteristics between the pixel 101 having the small second overlapping area S2 and the pixel 101 having the large second overlapping area S2.

A material of the second separated via 825 is any of a metal, a metal compound, and the like. For example, the metal is any of copper, tungsten, cobalt, and the like. The metal compound is any of a metal nitride, a metal oxide, and the like. The second separated via 825 may be formed from polycrystalline silicon provided with conductivity. The material of the second separated via 825 may be the same as or different from the material of the first separated via 725.

### Camera System

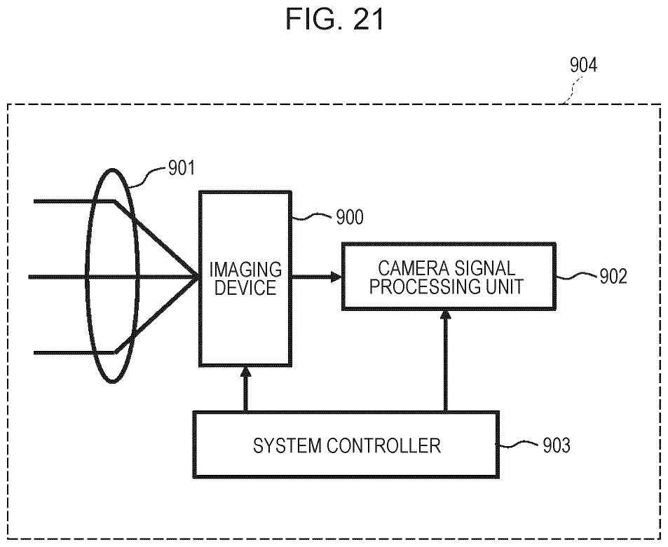

FIG. 21 is a configuration diagram of a camera system 904 according to an example.

The camera system 904 includes a lens optical system 901, an imaging device 900, a system controller 903, and a camera signal processing unit 902.

For example, the lens optical system 901 includes an automatic focusing lens, a zoom lens, a diaphragm, and the like. The lens optical system 901 focuses the light 75 onto an imaging surface of the imaging device 900. Any of the imaging devices 100 to 800 according to the first to eighth embodiments can be used as the imaging device 900.

The system controller 903 controls the entire camera system 904. For example, the system controller 903 can be implemented by a microcomputer.

The camera signal processing unit 902 functions as a signal processing circuit that processes an output signal from the imaging device 900. The camera signal processing unit 902 carries out processing such as gamma correction, color interpolation processing, spatial interpolation processing, and automatic white balancing. For example, the camera signal processing unit 902 can be implemented by a digital signal processor (DSP) and the like.

The camera signal processing unit 902 can obtain imaging data from the imaging device 900, and perform sensing of the imaging data. For example, the camera signal processing unit 902 can compute a distance to a following vehicle by means of the sensing. As described above, the camera signal processing unit 902 may detect a specific subject in the obtained imaging data, and start the sensing in response to the detection.

According to the camera system of this example, it is possible to provide a camera system that reduces shading attributed to deterioration in sensitivity at the peripheral portion Pb of the pixel region Px.

The imaging device according to the present disclosure is applicable to various camera systems and sensor systems including a digital still camera, a camera for medical use, a monitoring camera, a car-mounted camera, a digital single-lens reflex camera, a digital mirrorless single-lens camera, and the like.

What is claimed is:

1. An imaging device comprising:
pixels; and
pixel electrodes, wherein
each of the pixels includes
a semiconductor substrate,
a photoelectric conversion layer that converts light into electric charges, and
a corresponding pixel electrode out of the pixel electrodes,
the corresponding pixel electrode collects the electric charges, and a pitch of the pixel electrodes is greater than a pitch of the pixels.

2. The imaging device according to claim 1, further comprising:
charge accumulating regions that are located in the semiconductor substrate and that accumulate the electric charges, wherein
each of the plurality of pixels further includes a corresponding charge accumulating region out of the charge accumulating regions, and
the pitch of the pixels is equivalent to a pitch of the charge accumulating regions.

3. The imaging device according to claim 1, further comprising:
charge accumulating regions that are located in the semiconductor substrate and that accumulate the electric charges;
first electric pathways; and
first connectors, wherein
each of the pixels further includes
a corresponding charge accumulating region out of the charge accumulating regions,
a corresponding first electric pathway out of the first electric pathways, and
a corresponding first connector out of the first connectors,
the corresponding first electric pathway electrically connects the corresponding pixel electrode and the corresponding charge accumulating region and includes the corresponding first connector,
the corresponding first connector is physically connected to the corresponding pixel electrode, and
the pitch of the pixels is equivalent to a pitch of the first connectors.

4. The imaging device according to claim 1, further comprising:
charge accumulating regions that are located in the semiconductor substrate and that accumulate the electric charges;
first electric pathways; and
second connectors, wherein
each of the pixels further includes
a corresponding charge accumulating region out of the charge accumulating regions,
a corresponding first electric pathway out of the first electric pathways, and
a corresponding second connector out of the second connectors,
the corresponding first electric pathway electrically connects the corresponding pixel electrode and the corresponding charge accumulating region and includes the corresponding second connector,
the corresponding second connector is physically connected to the corresponding charge accumulating region, and
the pitch of the pixels is equivalent to a pitch of the second connectors.

5. The imaging device according to claim 1, further comprising:
charge accumulating regions that are located in the semiconductor substrate and that accumulate the electric charges;
first electric pathways; and
through holes, wherein
each of the pixels further includes
a corresponding charge accumulating region out of the charge accumulating regions,
an insulating film that covers the semiconductor substrate,
a corresponding through hole out of the through holes, the corresponding through hole passing through the insulating film, and
a corresponding first electric pathway out of the first electric pathways,
the corresponding first electric pathway electrically connects the corresponding pixel electrode and the corresponding charge accumulating region and passes through the corresponding through hole, and
the pitch of the pixels is equivalent to a pitch of the through holes.

6. The imaging device according to claim 1, further comprising:
wires, wherein
the pixels are arrayed to form rows and columns,
on each of the columns, the pitch of the pixel electrodes is greater than the pitch of the pixels,
each of the wires extends along a corresponding row out of the rows,
the wires are arranged in a direction of the columns at mutually equal intervals, and
the corresponding pixel electrode overlaps a corresponding wire out of the wires in a plan view.

7. The imaging device according to claim 1, further comprising:
separated electrodes;
second electric pathways; and
pads, wherein
each of the separated electrodes, a corresponding second electric pathway out of the second electric pathways, and a corresponding pad out of the pads are electrically connected in this order,
each of the separated electrodes is located between two pixel electrodes located adjacent to each other out of the pixel electrodes,
each of the separated electrodes is electrically separated from the two pixel electrodes,
a pitch of the separated electrodes is different from a pitch of the pads, and each of the separated electrodes overlaps the corresponding pad in a plan view.

8. The imaging device according to claim 7, further comprising:
a first wiring layer; and
a second wiring layer, wherein
the semiconductor substrate, the second wiring layer, the first wiring layer, and the pixel electrodes are located in this order, and
the second wiring layer includes the pads.

9. The imaging device according to claim 1, wherein
each of the pixels further includes a first wiring layer opposed to the corresponding pixel electrode,
a pixel region is formed by the pixels,
the pixel region includes a central portion and a peripheral portion located outside of the central portion,
the pixels include a central pixel located at the central portion of the pixel region and a peripheral pixel located at the peripheral portion of the pixel region, and
when an area of overlap between the corresponding pixel electrode and the first wiring layer in a plan view is defined as an overlapping area, the overlapping area of the central pixel is equal to the overlapping area of the peripheral pixel.

10. The imaging device according to claim 1, further comprising:
color filters, wherein
each of the pixels further includes a corresponding color filter out of the color filters,
in each of the pixels, the corresponding color filter, the photoelectric conversion layer, and the corresponding pixel electrode are arranged in this order, and
a pitch of the color filters is less than the pitch of the pixels.

11. The imaging device according to claim 1, further comprising:
microlenses, wherein
each of the pixels further includes a corresponding microlens out of the microlenses,
in each of the pixels, the corresponding microlens, the photoelectric conversion layer, and the corresponding pixel electrode are arranged in this order, and
a pitch of the microlenses is less than the pitch of the pixels.

12. The imaging device according to claim 1, wherein
the pixels are arrayed to form rows and columns,
on at least one of the rows, the pitch of the pixel electrodes is greater than the pitch of the pixels, and
on at least one of the columns, the pitch of the pixel electrodes is greater than the pitch of the pixels.

13. The imaging device according to claim 12, wherein
on each of the rows, the pitch of the pixel electrodes is greater than the pitch of the pixels, and
on each of the columns, the pitch of the pixel electrodes is greater than the pitch of the pixels.
